(19) United States
(12) Patent Application Publication
(10) Pub. No.: US 2026/0245649 A1
(43) Pub. Date: Aug. 20, 2026

(54) FAST DUO-READ MODE FOR BIT FLIPS DETECTION

(71) Applicant: Sandisk Technologies, Inc., Milpitas, CA (US)

(72) Inventors: Xuan TIAN, Shanghai (CN); Liang LI, Shanghai (CN); Jiahui YUAN, Fremont, CA (US)

(73) Assignee: Sandisk Technologies, Inc., Milpitas, CA (US)

(21) Appl. No.: 19/057,290

(22) Filed: Feb. 19, 2025

(51) Int. Cl. G11C 29/44; G11C 29/12

(52) U.S. Cl. CPC G11C 29/44; G11C 29/12005

(57) ABSTRACT

A non-volatile memory system reads data from non-volatile memory cells. Sometimes, the read process fails. The system determines whether a read failure is due to a physical defect or a non-physical defect reliability issue based on which non-volatile memory cells flip output bits when the non-volatile memory cells are sensed at a particular read reference voltage of an initial set read reference voltages used before the read failure sequentially with being sensed at a corresponding particular read reference voltage of an updated set of read reference voltages without sensing therebetween at a different read reference voltage of either the initial set read reference voltages or the updated set read reference voltages. If the read process failed due to a physical defect, the corresponding block of non-volatile memory cells may be retired. If the read process failed due to a non-physical defect reliability issue, the block need not be retired.

### BACKGROUND

The present disclosure relates to non-volatile storage.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

Modern storage systems such as, for example, solid state drives typically contain a number of semiconductor dies with each die containing memory cells such as on NAND strings. Each die may contain one or more planes with each plane containing a large number of blocks. Each block contains a large number of memory cells such as NAND strings. A NAND string contains memory cell transistors connected in series, a drain side select gate at one end, and a source side select gate at the other end. Each NAND string is associated with a bit line. A block typically has many word lines that provide voltages to the control gates of the memory cell transistors. In some architectures, each word line connects to the control gate of one memory cell on each respective NAND string in the block. The block is associated with a source line. The source side select gates are used to connect or disconnect the NAND channels from the source line.

The memory cells are programmed one group at a time. The unit of programming is typically referred to as a page. Typically, the memory cells are programmed to a number of data states. Using a greater number of data states allows for more bits to be stored per memory cell. For example, four data states may be used to store two bits per memory cell, eight data states may be used in order to store three bits per memory cell, sixteen data states may be used to store four bits per memory cell, etc. Some memory cells may be programmed to a data state by storing charge in the memory cell. For example, the threshold voltage (Vt) of a NAND memory cell can be set to a target Vt by programming charge into a charge storage region such as a charge trapping layer. The amount of charge stored in the charge trapping layer establishes the Vt of the memory cell. At the end of a successful programming process, each memory cell's Vt should be within one of a number of Vt distributions.

Once the memory cells in the memory device have been programmed, data may be read from the memory cells by sensing the programmed data states of the memory cells. However, sensed data states can sometimes vary from the data states initially written to due to one or more factors. Error detection and correction decoding can be used to detect and correct data errors resulting from sensed data states that do not match data states initially written to. Typically, the user data is encoded as ECC (error correction code) codewords prior to programming. Therefore, an ECC engine may be used to correct errors in the encoded user data. However, there is a limit as to how many bits in the data read from the memory cells can be in error in order for the ECC algorithm to successfully correct all errors. Therefore, storage systems typically do not rely only on correcting errors in ECC codewords. Many storage systems employ one or more techniques to recover from read failures such as the failure to decode ECC codewords programmed into that block. One technique to recover from a read failure is to dynamically adjust (i.e., calibrate) the read reference voltages and then retry the read process for the memory cells with the adjusted read reference voltages. The read reference voltages can be adjusted/calibrated using a number of different techniques.

One reason for a read failure is due to intrinsic reliability issues (non-physical defect reliability issues). Over time the amount of charge that is stored in the charge storage region of the memory cell may change, thereby leading to a change in the Vt of the memory cell. The amount of charge could change due to program disturb, read disturb, or simply charge leakage over time. Program disturb refers to the unintended change to the Vt of a memory cell when programming a different cell. Read disturb refers to the unintended change to the Vt of a memory cell when reading that cell or a different cell. Charge leakage over time is referred to a data retention issue and more briefly “data retention” (DR).

Another reason for a read failure is due to a physical defect associated with the block containing the memory cells. Example physical defects include, but are not limited to, shorts such as word line to word line shorts, word line to memory cell shorts, etc. If such physical defects are detected prior to shipping the device to the customer, the block having the physical defect can be retired. However, physical defects can develop (e.g., grow) over time. It is important to detect a growing physical defect early prior to the physical defect leading to a read error that the memory system has difficulty recovering from or is unable to recover from.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIG. 2C depicts details of an individual sense block.

FIGS. 3A and 3B depict different embodiments of integrated memory assemblies.

FIG. 4 is a perspective view of a portion of one embodiment of a monolithic three dimensional memory structure.

FIG. 4A is a block diagram of one embodiment of a memory structure having two planes.

FIG. 4B depicts a top view of a portion of one embodiment of a block of memory cells.

FIG. 4C depicts a cross sectional view of a portion of one embodiment of a block of memory cells.

FIG. 4D depicts a cross sectional view of a portion of one embodiment of a block of memory cells.

FIG. 4E is a cross sectional view of one embodiment of a vertical column of memory cells.

FIG. 4F is a schematic of a plurality of NAND strings in multiple regions of a same block.

FIG. 5A depicts threshold voltage distributions.

FIG. 5B depicts threshold voltage distributions.

FIG. 5C depicts threshold voltage distributions.

FIG. 5D depicts threshold voltage distributions.

FIG. 6 depicts threshold voltage distributions.

FIG. 7 is a flow chart describing one embodiment of a process for reading non-volatile memory.

FIG. 8 is a flow chart describing one embodiment of a process for determining whether read failure is due to a physical defect or a non-physical defect reliability issue based on which non-volatile memory cells flip output bits when memory cells are sensed at an initial set of read reference voltages and at updated read reference voltages.

FIG. 9 depicts threshold voltage distributions.

FIG. 10 is a signal diagram depicting the word line voltage (e.g., applied to control gates) applied to memory cells during the reading of a page of data.

FIG. 11 is a flow chart describing one embodiment of a process for sensing an initial set of read reference voltages and at updated read reference voltages.

FIG. 12 is a signal diagram depicting the word line voltage (e.g., applied to control gates) applied to memory cells during the reading of a page of data.

FIG. 13 is a signal diagram depicting the word line voltage (e.g., applied to control gates) applied to memory cells during the reading of a page of data.

FIG. 14 is a flow chart describing one embodiment of a process for sensing an initial set of read reference voltages and at updated read reference voltages.

### DETAILED DESCRIPTION

Technology is disclosed for retrying failed reads of non-volatile memory such as NAND. The memory system retries the failed read using one or more different read techniques than the failed read until the read is successful. The memory system may use different read reference voltages for read retries than the read reference voltages used in the failed read. After a successful read retry the memory system determines whether the original read failed due to a physical defect or a non-physical defect reliability issue. If there is a physical defect the memory cells may be retired. In one embodiment, the entire block of memory cells having the physical defect is retired. However, if the read failed is due to a non-physical defect reliability issue, then the memory cells may continue to be used.

In one embodiment, the memory system determines whether a failed read is due to a physical defect or a non-physical defect reliability issue based on which non-volatile memory cells flip output bits when the non-volatile memory cells are sensed at a particular read reference voltage of an initial set read reference voltages used before the read failure sequentially with being sensed at a corresponding particular read reference of an updated set of read reference voltages without sensing therebetween at a different read reference voltage of either the initial set read reference voltages or the updated set read reference voltages.

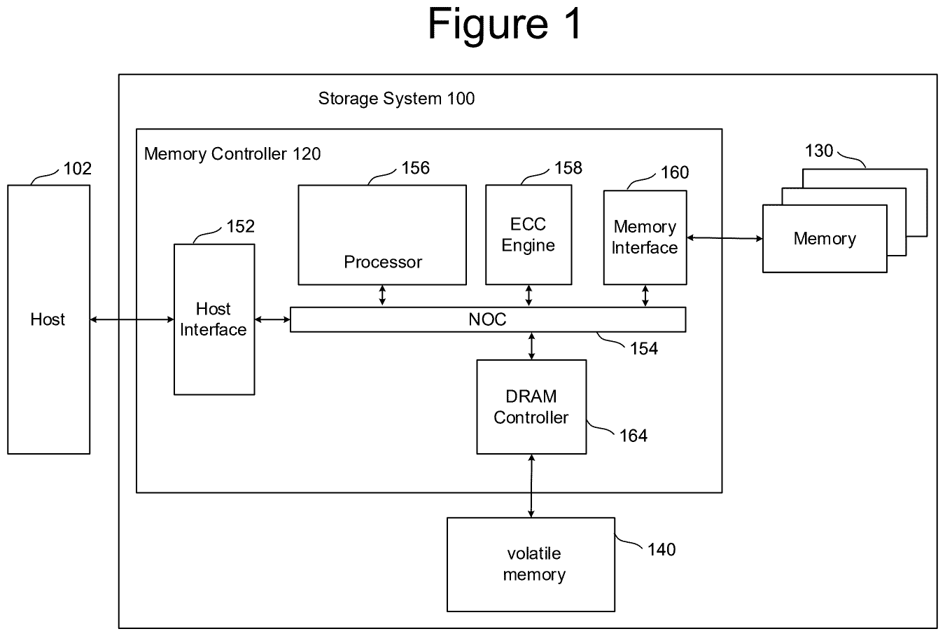

FIG. 1 is a block diagram of one embodiment of a storage system 100 that implements the proposed technology described herein. In one embodiment, storage system 100 is a solid state drive (“SSD”). Storage system 100 can also be a memory card, USB drive or other type of storage system. The proposed technology is not limited to any one type of memory system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 connected to non-volatile memory 130 and local high speed volatile memory 140 (e.g., DRAM). Local high speed volatile memory 140 is used by memory controller 120 to perform certain functions. For example, local high speed volatile memory 140 stores logical to physical address translation tables (“L2P tables”).

Memory controller 120 comprises a host interface 152 that is connected to and in communication with host 102. In one embodiment, host interface 152 implements a NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and DRAM controller 164. DRAM controller 164 is used to operate and communicate with local high speed volatile memory 140 (e.g., DRAM). In other embodiments, local high speed volatile memory 140 can be SRAM or another type of volatile memory.

ECC engine 158 performs error correction services. For example, ECC engine 158 performs data encoding and decoding, as per the implemented ECC technique. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory dies. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a memory die 130 and a subset of the L2P tables are cached (L2P cache) in the local high speed volatile memory 140.

Memory interface 160 communicates with non-volatile memory 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

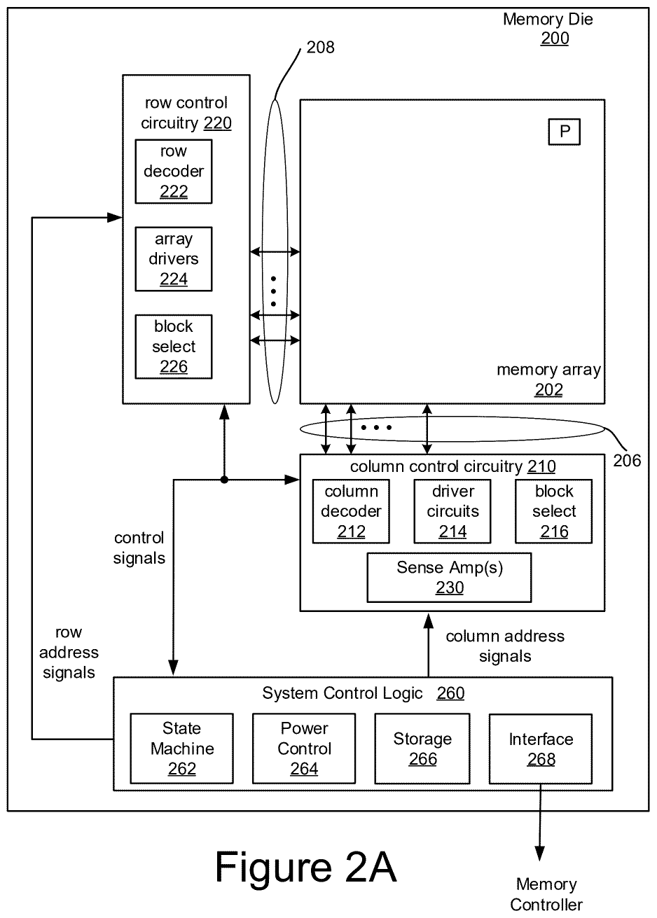

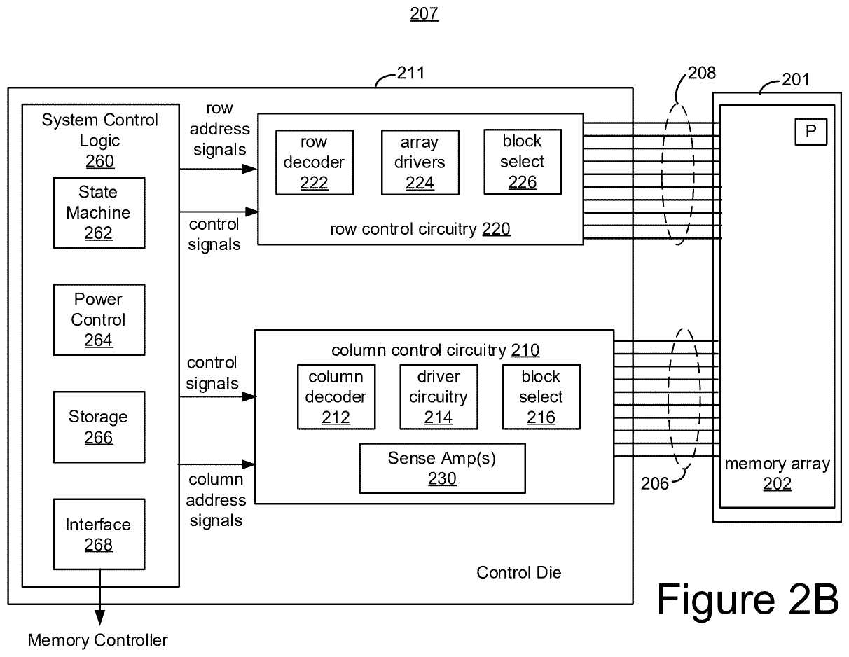

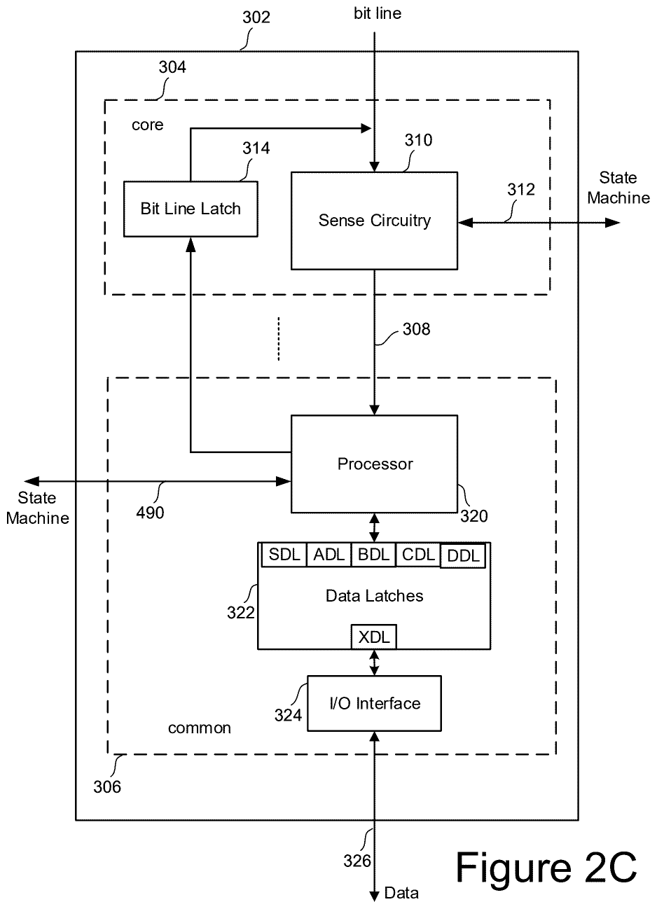

In one embodiment, non-volatile memory 130 comprises one or more memory die. FIG. 2A is a functional block diagram of one embodiment of a memory die 200 that comprises non-volatile memory 130. Each of the one or more memory die of non-volatile memory 130 can be implemented as memory die 200 of FIG. 2A. The components depicted in FIG. 2A are electrical circuits. Memory die 200 includes a memory array 202 that can comprises non-volatile memory cells, as described in more detail below. The array terminal lines of memory array 202 include the various layer(s) of word lines organized as rows, and the various layer(s) of bit lines organized as columns. However, other orientations can also be implemented. Memory die 200 includes row control circuitry 220, whose outputs 208 are connected to respective word lines of the memory array 202. Row control circuitry 220 receives a group of M row address signals and one or more various control signals from System Control Logic circuit 260, and typically may include such circuits as row decoders 222, array terminal drivers 224, and block select circuitry 226 for both reading and writing (programming) operations. Row control circuitry 220 may also include read/write circuitry. Memory die 200 also includes column control circuitry 210 including sense amplifier(s) 230 whose input/outputs 206 are connected to respective bit lines of the memory array 202. Although only single block is shown for array 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers.

System control logic 260 receives data and commands from memory controller 120 and provides output data and status to the host. In some embodiments, the system control logic 260 (which comprises one or more electrical circuits) include state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 262 can also include a power control module 264 that controls the power and voltages supplied to the rows and columns of the memory structure 202 during memory operations and may include charge pumps and regulator circuit for creating regulating voltages. System control logic 262 includes storage 366 (e.g., RAM, registers, latches, etc.), which may be used to store parameters for operating the memory array 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 302 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or another wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile memory 130 of storage system 100. The integrated memory assembly 207 includes two types of semiconductor die (or more succinctly, “die”). Memory die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory die 201. In some embodiments, the memory die 201 and the control die 211 are bonded together.

FIG. 2B shows an example of the peripheral circuitry, including control circuits, formed in a peripheral circuit or control die 211 coupled to memory structure 202 formed in memory die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory die 201. In some embodiments, some of the circuitry in the system control logic 260 is located on the on the memory die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory 2 die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including sense amplifier(s) 230 on the control die 211 coupled to memory structure 202 on the memory die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each of electrical path 208 may correspond to a word line, dummy word line, or select gate line. Additional electrical paths may also be provided between control die 211 and memory die 201.

For purposes of this document, the phrases “a control circuit” or “one or more control circuits” can include any one of or any combination of memory controller 120, state machine 262, all or a portion of system control logic 260, all or a portion of row control circuitry 220, all or a portion of column control circuitry 210, a microcontroller, a microprocessor, and/or other similar functioned circuits. The control circuit can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

FIG. 2C is a block diagram depicting an individual sense block 302 of sense amplifiers 230 partitioned into a core portion 304 (referred to as a sense module 304) and a common portion 306. In one embodiment, there will be a separate sense module 304 for each bit line and one common portion 306 for a set of multiple sense modules 304. In one example, a sense block 302 will include one common portion 306 connected to eight, twelve, or sixteen sense modules 304. Each of the sense modules 304 in a group will communicate with the associated common portion 306 via a data bus 308. In one embodiment, sense amplifiers 230 will include many sense blocks 302.

Sense module 304 comprises sense circuitry 310 that determines whether a conduction current in a connected bit line is above or below a predetermined level or, in voltage based sensing, whether a voltage level in a connected bit line is above or below a predetermined level. The sense circuitry 310 is to receive control signals from the state machine via input lines 312. In some embodiments, sense circuitry 310 includes a circuit commonly referred to as a sense amplifier. Sense module 304 also includes a bit line latch 314 that is used to set a voltage condition on the connected bit line. For example, a predetermined state latched in bit line latch 314 will result in the connected bit line being pulled to a state designating program inhibit (e.g., VDD).

Common portion 306 comprises a processor 320, data latches 322 and an I/O Interface 324 coupled between the set of data latches 322 and data bus 326. Processor 320 performs computations. For example, one of its functions is to determine the data stored in the sensed memory cell and store the determined data in the set of data latches. The set of data latches 322 is used to store data bits determined by processor 320 during a read operation. It is also used to store data bits imported from the data bus 326 during a program operation. The imported data bits represent write data meant to be programmed into the memory. I/O interface 324 provides an interface between data latches 322 and the data bus 326.

During read or sensing, the operation of the system is under the control of state machine 262 that controls (using power control 264) the supply of different control gate or other bias voltages to the addressed memory cell(s). As it steps through the various predefined control gate voltages corresponding to the various memory states supported by the memory, the sense module 304 may trip at one of these voltages and an output will be provided from sense module 304 to processor 320 via bus 308. At that point, processor 320 determines the resultant memory state by consideration of the tripping event(s) of the sense module 304 and the information about the applied control gate voltage from the state machine via signal lines 490. It then computes a binary encoding for the memory state and stores the resultant data bits into data latches 322. In another embodiment, bit line latch 314 serves double duty, both as a latch for latching the output of the sense module 304 and also as a bit line latch as described above.

Data latch stack 322 contains a stack of data latches corresponding to an associated sense module 304. In one embodiment, there are three, four or another number of data latches per sense module 304. In one embodiment, the latches are each one bit (e.g., one bit per sense module 304). In one embodiment, the latches for each sense module 304 will be referred to as SDL, XDL, ADL, BDL, CDL, and DDL. Thus, in one embodiment, each sense module 304 has its own set of SDL, XDL, ADL, BDL, CDL, and DDL. In the embodiments discussed here, the latch XDL is a transfer latch used to exchange data with the I/O interface 324. In addition to a first sense amplifier data latch SDL, the additional latches ADL, BDL, CDL, and DDL can be used to hold multi-state data, where the number of such latches typically reflects the number of bits stored in a memory cell. For example, in 3-bit per memory cell multi-level cell (MLC) memory format, the three sets of latches ADL, BDL, CDL can be used for upper, middle, and lower page data. In a 2-bit per cell embodiment, only ADL and BDL might be used. In a 4-bit per memory cell multi-level cell memory format, the four sets of latches ADL, BDL, CDL, and DDL can be used for upper, middle, lower and top page data. In embodiments discussed below, the latches ADL, BDL, CDL, DDL, SDL and XDL can transfer data between themselves and the bit line latch 324.

In some embodiments data read from a memory cell or data to be programmed into a memory cell will first be stored in XDL. In case the data is to be programmed into a memory cell, the system can program the data into the memory cell from XDL. In one embodiment, the data is programmed into the memory cell entirely from XDL before the next operation proceeds. In other embodiments, as the system begins to program a memory cell through XDL, the system also transfers the data stored in XDL into ADL in order to reset XDL. Before data is transferred from XDL into ADL, the data kept in ADL is transferred to BDL, flushing out whatever data (if any) is being kept in BDL, and similarly for BDL and CDL. Once data has been transferred from XDL into ADL, the system continues (if necessary) to program the memory cell through ADL, while simultaneously loading the data to be programmed into a memory cell on the next word line into XDL, which has been reset. By performing the data load and programming operations simultaneously, the system can save time and thus perform a sequence of such operations faster.

During program or verify, the data to be programmed is stored in the set of data latches 322 from the data bus 326. During the verify process, Processor 320 monitors the verified memory state relative to the desired memory state. When the two are in agreement, processor 320 sets the bit line latch 314 so as to cause the bit line to be pulled to a state designating program inhibit. This inhibits the memory cell coupled to the bit line from further programming even if it is subjected to programming pulses on its control gate. In other embodiments the processor initially loads the bit line latch 468 and the sense circuitry sets it to an inhibit value during the verify process.

In some implementations (but not required), the data latches are implemented as a shift register so that the parallel data stored therein is converted to serial data for data bus 326, and vice versa. In one preferred embodiment, all the data latches corresponding to the read/write block of m memory cells can be linked together to form a block shift register so that a block of data can be input or output by serial transfer. In particular, the bank of read/write modules is adapted so that each of its set of data latches will shift data in to or out of the data bus in sequence as if they are part of a shift register for the entire read/write block.

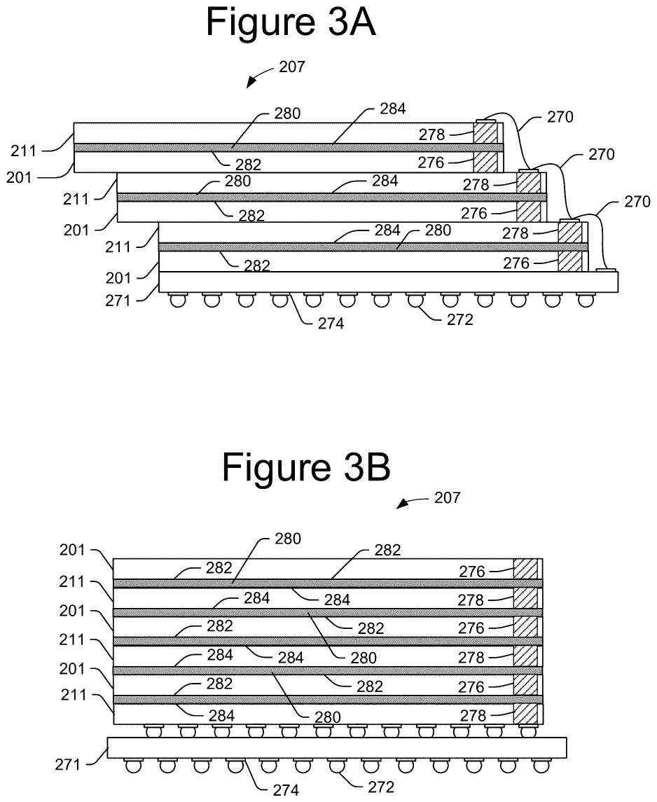

In some embodiments, there is more than one control die 211 and more than one memory die 201 in an integrated memory assembly 207. In some embodiments, the integrated memory assembly 207 includes a stack of multiple control die 211 and multiple memory die 201. FIG. 3A depicts a side view of an embodiment of an integrated memory assembly 207 stacked on a substrate 271 (e.g., a stack comprising control dies 211 and memory dies 201). The integrated memory assembly 207 has three control dies 211 and three memory dies 201. In some embodiments, there are more than three memory dies 201 and more than three control die 211.

Each control die 211 is affixed (e.g., bonded) to at least one of the memory dies 201. Some of the bond pads 282/284 are depicted. There may be many more bond pads. A space between two dies 201, 211 that are bonded together is filled with a solid layer 280, which may be formed from epoxy or other resin or polymer. This solid layer 280 protects the electrical connections between the dies 201, 211, and further secures the dies together. Various materials may be used as solid layer 280, but in embodiments, it may be Hysol epoxy resin from Henkel Corp., having offices in California, USA.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control die 211 and three memory die 201. In some embodiments, there are many more than three memory dies 201 and many more than three control dies 211. In this example, each control die 211 is bonded to at least one memory die 201. Optionally, a control die 211 may be bonded to two or more memory die 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory die 201 may be bonded together. Bond pads on each die 201, 211 may be used to bond the two dies together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor dies including the bond pads. The film layer is provided around the bond pads. When the dies are brought together, the bond pads may bond to each other, and the film layers on the respective dies may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller (or greater) sizes and pitches.

Some embodiments may include a film on surface of the dies 201, 211. Where no such film is initially provided, a space between the dies may be under filled with an epoxy or other resin or polymer. The under-fill material may be applied as a liquid which then hardens into a solid layer. This under-fill step protects the electrical connections between the dies 201, 211, and further secures the dies together. Various materials may be used as under-fill material, but in embodiments, it may be Hysol epoxy resin from Henkel Corp., having offices in California, USA.

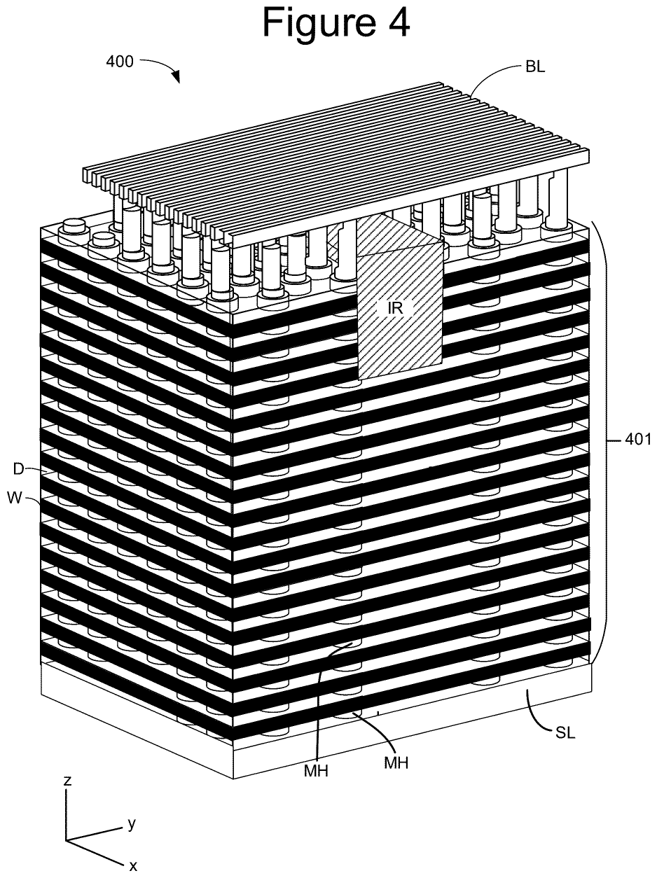

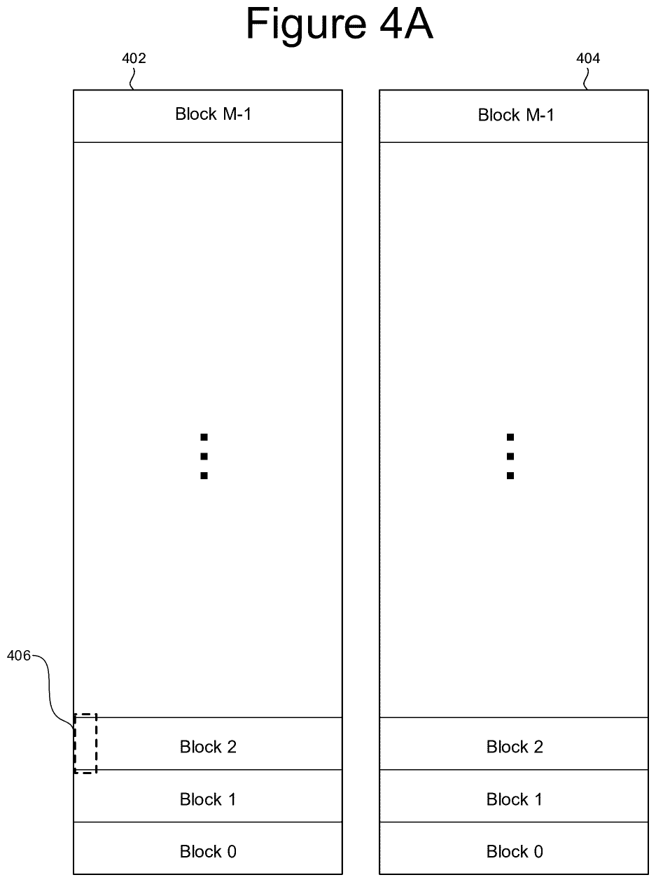

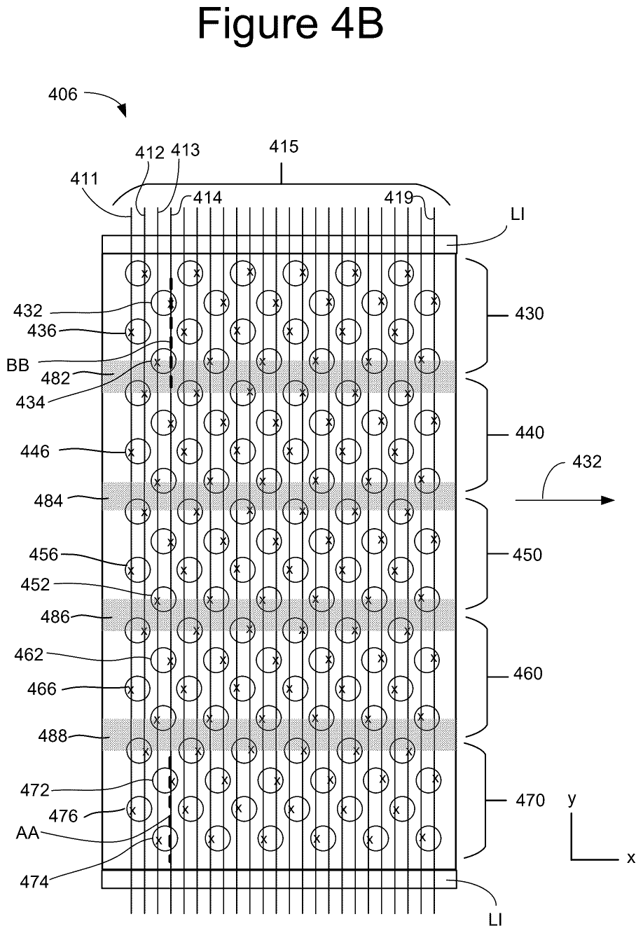

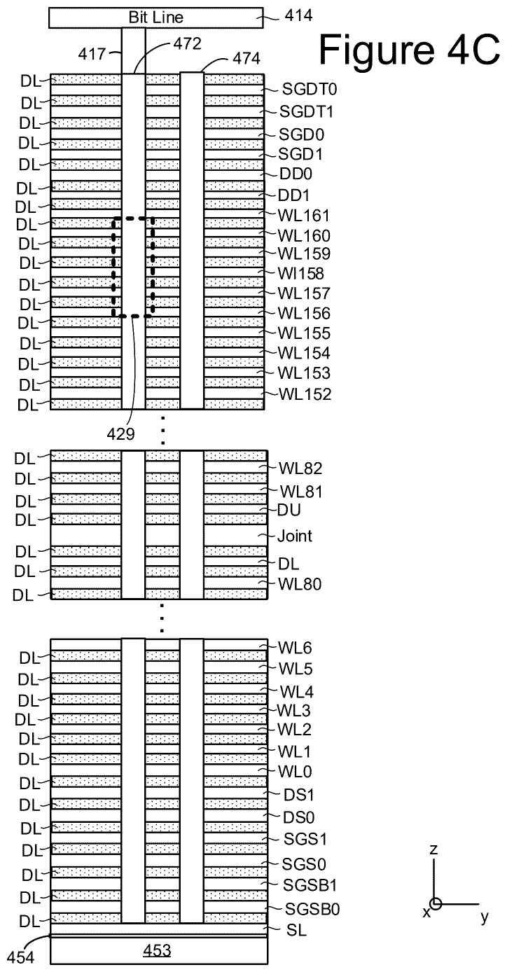

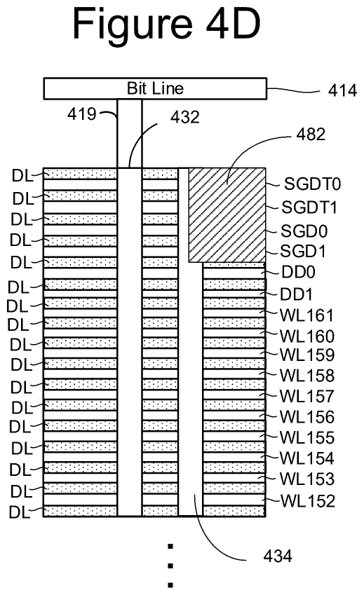

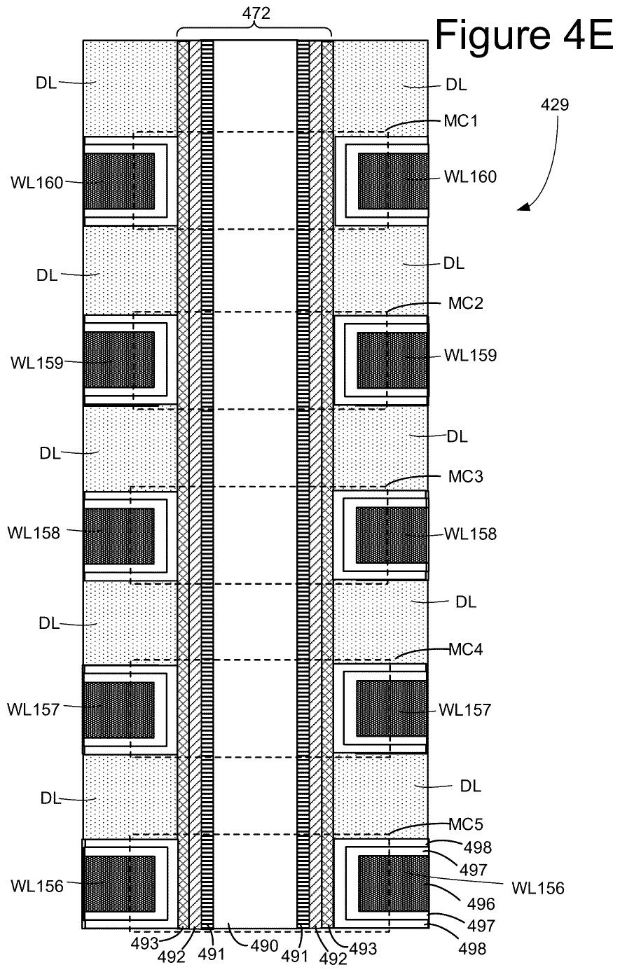

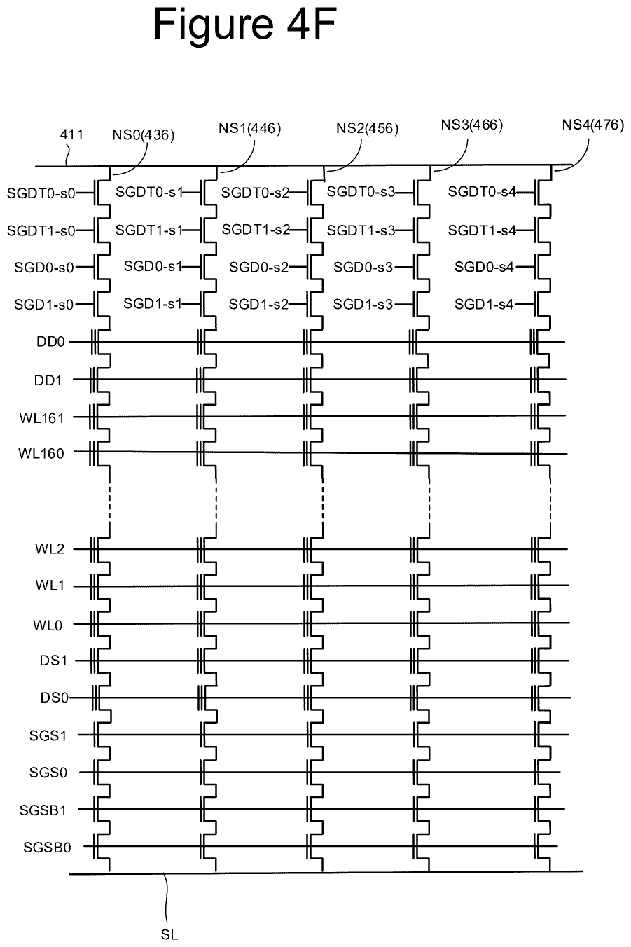

FIG. 4 is a perspective view of a portion of one example embodiment of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. As will be explained below, in one embodiment the alternating dielectric layers and conductive layers are divided into four or five (or a different number of) regions by isolation regions IR. FIG. 4 shows one isolation region IR separating two regions. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. Thus, the non-volatile memory cells are arranged in memory holes. More details of the three dimensional monolithic memory array that comprises memory structure 202 is provided below.

FIG. 4A is a block diagram explaining one example organization of memory structure 202, which is divided into two planes 402 and 404. Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, blocks can be divided into sub-blocks and the sub-blocks can be the unit of erase. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows two planes 402/404, more or less than two planes can be implemented. In some embodiments, memory structure 202 includes eight planes.

FIGS. 4B-4G depict an example three dimensional (“3D”) NAND structure that corresponds to the structure of FIG. 4 and can be used to implement memory structure 202 of FIGS. 2A and 2B. FIG. 4B is a block diagram depicting a top view of a portion 406 of Block 2 of plane 402. As can be seen from FIG. 4B, the block depicted in FIG. 4B extends in the direction of 432. In one embodiment, the memory array has many layers; however, FIG. 4B only shows the top layer.

FIG. 4B depicts a plurality of circles that represent the memory holes, which are also referred to as vertical columns. Each of the memory holes/vertical columns include multiple select transistors (also referred to as a select gate or selection gate) and multiple memory cells. In one embodiment, each memory hole/vertical column implements a NAND string. For example, FIG. 4B labels a subset of the memory holes/vertical columns/NAND strings 432, 436, 446, 456, 462, 466, 472, 474 and 476.

FIG. 4B also depicts a set of bit lines 415, including bit lines 411, 412, 413, 414, . . . 419. FIG. 4B shows twenty four bit lines because only a portion of the block is depicted. It is contemplated that more than twenty four bit lines connected to memory holes/vertical columns of the block. Each of the circles representing memory holes/vertical columns has an “x” to indicate its connection to one bit line. For example, bit line 411 is connected to memory holes/vertical columns 436, 446, 456, 466 and 476.

The block depicted in FIG. 4B includes a set of isolation regions 482, 484, 486 and 488, which are formed of SiO₂; however, other dielectric materials can also be used. Isolation regions 482, 484, 486 and 488 serve to divide the top layers of the block into five regions; for example, the top layer depicted in FIG. 4B is divided into regions 430, 440, 450, 460 and 470. In one embodiment, the isolation regions only divide the layers used to implement select gates so that NAND strings in different regions can be independently selected. In one example implementation, a bit line connects to one memory hole/vertical column/NAND string in each of regions 430, 440, 450, 460 and 470. In that implementation, each block has twenty four rows of active columns and each bit line connects to five rows in each block. In one embodiment, all of the five memory holes/vertical columns/NAND strings connected to a common bit line are connected to the same set of word lines; therefore, the system uses the drain side select lines to choose one (or another subset) of the five to be subjected to a memory operation (program, verify, read, and/or erase).

FIG. 4B also shows Line Interconnects LI, which are metal connections to the source line SL from above the memory array. Line Interconnects LI are positioned adjacent regions 430 and 470.

Although FIG. 4B shows each region 430, 440, 450, 460 and 470 having four rows of memory holes/vertical columns, five regions and twenty four rows of memory holes/vertical columns in a block, those exact numbers are an example implementation. Other embodiments may include more or less regions per block, more or less rows of memory holes/vertical columns per region and more or less rows of vertical columns per block. FIG. 4B also shows the memory holes/vertical columns being staggered. In other embodiments, different patterns of staggering can be used. In some embodiments, the memory holes/vertical columns are not staggered.

FIG. 4C depicts a portion of one embodiment of a three dimensional memory structure 202 showing a cross-sectional view along line AA of FIG. 4B. This cross sectional view cuts through memory holes/vertical columns (NAND strings) 472 and 474 of region 470 (see FIG. 4B). The structure of FIG. 4C includes two drain side select layers SGD0 and SGD; teo source side select layers SGS0 and SGS1; two drain side GIDL generation transistor layers SGDT0 and SGDT1; two source side GIDL generation transistor layers SGSB0 and SGSB1; two drain side dummy word line layers DD0 and DD1; two source side dummy word line layers DS0 and DS1; dummy word line layers DU and DL; one hundred and sixty two word line layers WL0-WL161 for connecting to data memory cells, and dielectric layers DL. Other embodiments can implement more or less than the numbers described above for FIG. 4C. In one embodiment, SGD0 and SGD1 are connected together; and SGS0 and SGS1 are connected together. In other embodiments, more or less number of SGDs (greater or lesser than two) are connected together, and more or less number of SGSs (greater or lesser than two) connected together.

In one embodiment, erasing the memory cells is performed using gate induced drain leakage (GIDL), which includes generating charge carriers at the GIDL generation transistors such that the carriers get injected into the charge trapping layers of the NAND strings to change threshold voltage of the memory cells. FIG. 4C shows two GIDL generation transistors at each end of the NAND string; however, in other embodiments there are more or less than three. Embodiments that use GIDL at both sides of the NAND string may have GIDL generation transistors at both sides. Embodiments that use GIDL at only the drain side of the NAND string may have GIDL generation transistors only at the drain side. Embodiments that use GIDL at only the source side of the NAND string may have GIDL generation transistors only at the source side.

FIG. 4C shows two GIDL generation transistors at each end of the NAND string. It is likely that charge carriers are only generated by GIDL at one of the two GIDL generation transistors at each end of the NAND string. Based on process variances during manufacturing, it is likely that one of the two GIDL generation transistors at an end of the NAND string is best suited for GIDL. For example, the GIDL generation transistors have an abrupt pn junction to generate the charge carriers for GIDL and, during fabrication, a phosphorous diffusion is performed at the polysilicon channel of the GIDL generation transistors. In some cases, the GIDL generation transistor with the shallowest phosphorous diffusion is the GIDL generation transistor that generates the charge carriers during erase. However, in some embodiments charge carriers can be generated by GIDL at multiple GIDL generation transistors at a particular side of the NAND string.

Memory holes/Vertical columns 472 and 474 are depicted protruding through the drain side select layers, source side select layers, dummy word line layers, GIDL generation transistor layers and word line layers. In one embodiment, each memory hole/vertical column comprises a vertical NAND string. Below the memory holes/vertical columns and the layers listed below is substrate 453, an insulating film 454 on the substrate, and source line SL. The NAND string of memory hole/vertical column 472 has a source end at a bottom of the stack and a drain end at a top of the stack. As in agreement with FIG. 4B, FIG. 4C show vertical memory hole/column 472 connected to bit line 414 via connector 417.

For ease of reference, drain side select layers; source side select layers, dummy word line layers, GIDL generation transistor layers and data word line layers collectively are referred to as the conductive layers. In one embodiment, the conductive layers are made from a combination of TiN and Tungsten. In other embodiments, other materials can be used to form the conductive layers, such as doped polysilicon, metal such as Tungsten, metal silicide, such as nickel silicide, tungsten silicide, aluminum silicide or the combination thereof. In some embodiments, different conductive layers can be formed from different materials. Between conductive layers are dielectric layers DL. In one embodiment, the dielectric layers are made from SiO₂. In other embodiments, other dielectric materials can be used to form the dielectric layers.

The non-volatile memory cells are formed along memory holes/vertical columns which extend through alternating conductive and dielectric layers in the stack. In one embodiment, the memory cells are arranged in NAND strings. The word line layers WL0-WL161 connect to memory cells (also called data memory cells). Dummy word line layers connect to dummy memory cells. A dummy memory cell does not store and is not eligible to store host data (data provided from the host, such as data from a user of the host), while a data memory cell is eligible to store host data. In some embodiments, data memory cells and dummy memory cells may have a same structure. Drain side select layers SGD0 and SGD1 are used to electrically connect and disconnect NAND strings from bit lines. Source side select layers SGS0 and SGS1 are used to electrically connect and disconnect NAND strings from the source line SL.

FIG. 4C shows that the memory array is implemented as a two tier architecture, with the tiers separated by a Joint area. In one embodiment it is expensive and/or challenging to etch so many word line layers intermixed with dielectric layers. To ease this burden, one embodiment includes laying down a first stack of word line layers (e.g., WL0-WL80) alternating with dielectric layers, laying down the Joint area, and laying down a second stack of word line layers (e.g., WL81-WL161) alternating with dielectric layers. The Joint area are positioned between the first stack and the second stack. In one embodiment, the Joint areas are made from the same materials as the word line layers. In other embodiments, there can no Joint area or there can be multiple Joint areas.

FIG. 4D depicts a portion of one embodiment of a three dimensional memory structure 202 showing a cross-sectional view along line BB of FIG. 4B. This cross sectional view cuts through memory holes/vertical columns (NAND strings) 432 and 434 of region 430 (see FIG. 4B). FIG. 4D shows the same alternating conductive and dielectric layers as FIG. 4C. FIG. 4D also shows isolation region 482. Isolation regions 482, 484, 486 and 488) occupy space that would have been used for a portion of the memory holes/vertical columns/NAND stings. For example, isolation region 482 occupies space that would have been used for a portion of memory hole/vertical column 434. More specifically, a portion (e.g., half the diameter) of vertical column 434 has been removed in layers SGDT0, SGDT1, SGD0, and SGD1 to accommodate isolation region 482. Thus, while most of the vertical column 434 is cylindrical (with a circular cross section), the portion of vertical column 434 in layers SGDT0, SGDT1, SGD0, and SGD1 has a semi-circular cross section. In one embodiment, after the stack of alternating conductive and dielectric layers is formed, the stack is etched to create space for the isolation region and that space is then filled in with SiO₂. This structure allows for separate control of SGDT0, SGDT1, SGD0, and SGD1 for regions 430, 440, 450, 460, and 470.

FIG. 4E depicts a cross sectional view of region 429 of FIG. 4C that includes a portion of memory hole/vertical column 472. In one embodiment, the memory holes/vertical columns are round; however, in other embodiments other shapes can be used. In one embodiment, memory hole/vertical column 472 includes an inner core layer 490 that is made of a dielectric, such as SiO₂. Other materials can also be used. Surrounding inner core 490 is polysilicon channel 491. Materials other than polysilicon can also be used. Note that it is the channel 491 that connects to the bit line and the source line. Surrounding channel 491 is a tunneling dielectric 492. In one embodiment, tunneling dielectric 492 has an ONO structure. Surrounding tunneling dielectric 492 is charge trapping layer 493, such as (for example) Silicon Nitride. Other memory materials and structures can also be used. The technology described herein is not limited to any particular material or structure.

FIG. 4E depicts dielectric layers DL as well as word line layers WL160, WL159, WL158, WL157, and WL156. Each of the word line layers includes a word line region 496 surrounded by an aluminum oxide layer 497, which is surrounded by a blocking oxide layer 498. In other embodiments, the blocking oxide layer can be a vertical layer parallel and adjacent to charge trapping layer 493. The physical interaction of the word line layers with the vertical column forms the memory cells. Thus, a memory cell, in one embodiment, comprises channel 491, tunneling dielectric 492, charge trapping layer 493, blocking oxide layer 498, aluminum oxide layer 497 and word line region 496. For example, word line layer WL160 and a portion of memory hole/vertical column 472 comprise a memory cell MC1. Word line layer WL159 and a portion of memory hole/vertical column 472 comprise a memory cell MC2. Word line layer WL158 and a portion of memory hole/vertical column 472 comprise a memory cell MC3. Word line layer WL157 and a portion of memory hole/vertical column 472 comprise a memory cell MC4. Word line layer WL156 and a portion of memory hole/vertical column 472 comprise a memory cell MC5. In other architectures, a memory cell may have a different structure; however, the memory cell would still be the storage unit.

When a memory cell is programmed, electrons are stored in a portion of the charge trapping layer 493 which is associated with (e.g. in) the memory cell. These electrons are drawn into the charge trapping layer 493 from the channel 491, through the tunneling dielectric 492, in response to an appropriate voltage on word line region 496. The threshold voltage (Vth) of a memory cell is increased in proportion to the amount of stored charge. In one embodiment, the programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as GIDL.

FIG. 4F is a schematic diagram of a portion of the three dimensional memory array 202 depicted in in FIGS. 4-4E. FIG. 4F shows physical data word lines WL0-WL161 running across the entire block. The structure of FIG. 4F corresponds to a portion 406 in Block 2 of FIG. 4A, including bit line 411. Within the block, in one embodiment, each bit line is connected to five NAND strings, one in each region of regions 430, 440, 450, 460, 470. Thus, FIG. 4F shows bit line 411 connected to NAND string NS0 (which corresponds to memory hole/vertical column 436 of region 430), NAND string NS1 (which corresponds to memory hole/vertical column 446 of region 440), NAND string NS2 (which corresponds to vertical column 456 of region 450), NAND string NS3 (which corresponds to memory hole/vertical column 466 of region 460), and NAND string NS4 (which corresponds to memory hole/vertical column 476 of region 470).

Drain side select line/layer SGD0 is separated by isolation regions isolation regions 482, 484, 486 and 488 to form SGD0-s0, SGD0-s1, SGD0-s2, SGD0-s3 and SGD0-s4 in order to separately connect to and independently control regions 430, 440, 450, 460, 470. Similarly, drain side select line/layer SGD1 is separated by isolation regions 482, 484, 486 and 488 to form SGD1-s0, SGD1-s1, SGD1-s2, SGD1-s3 and SGD1-s4 in order to separately connect to and independently control regions 430, 440, 450, 460, 470; drain side GIDL generation transistor control line/layer SGDT0 is separated by isolation regions 482, 484, 486 and 488 to form SGDT0-s0, SGDT0-s1, SGDT0-s2, SGDT0-s3 and SGDT0-s4 in order to separately connect to and independently control regions 430, 440, 450, 460, 470; drain side GIDL generation transistor control line/layer SGDT1 is separated by isolation regions 482, 484, 486 and 488 to form SGDT1-s0, SGDT1-s1, SGDT1-s2, SGDT1-s3 and SGDT1-s4 in order to separately connect to and independently control regions 430, 440, 450, 460, 470.

FIG. 4F only shows NAND strings connected to bit line 411. However, a full schematic of the block would show every bit line and five vertical NAND strings (that are in separate regions) connected to each bit line.

Although the example memories of FIGS. 4-4F are three dimensional memory structure that includes vertical NAND strings with charge-trapping material, other (2D and 3D) memory structures can also be used with the technology described herein.

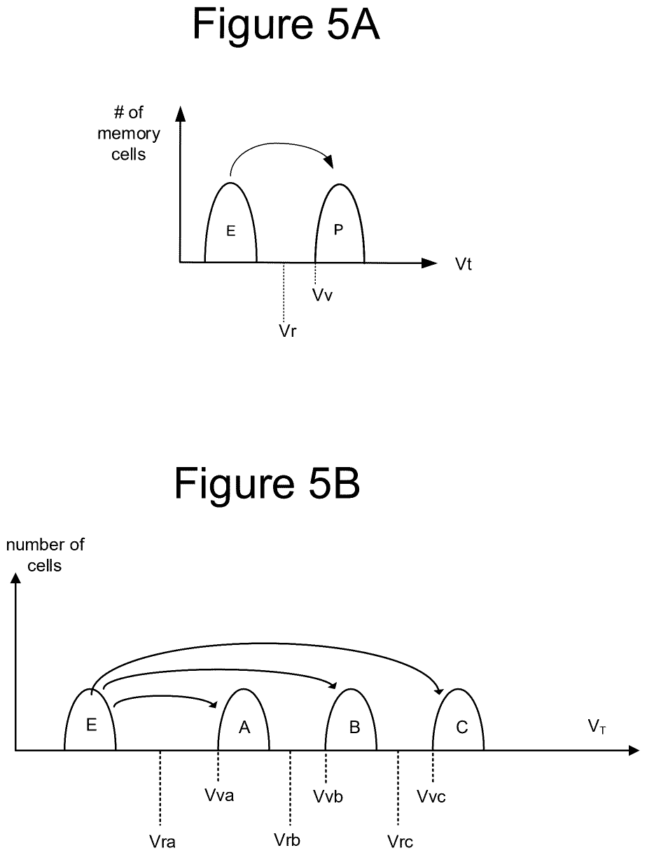

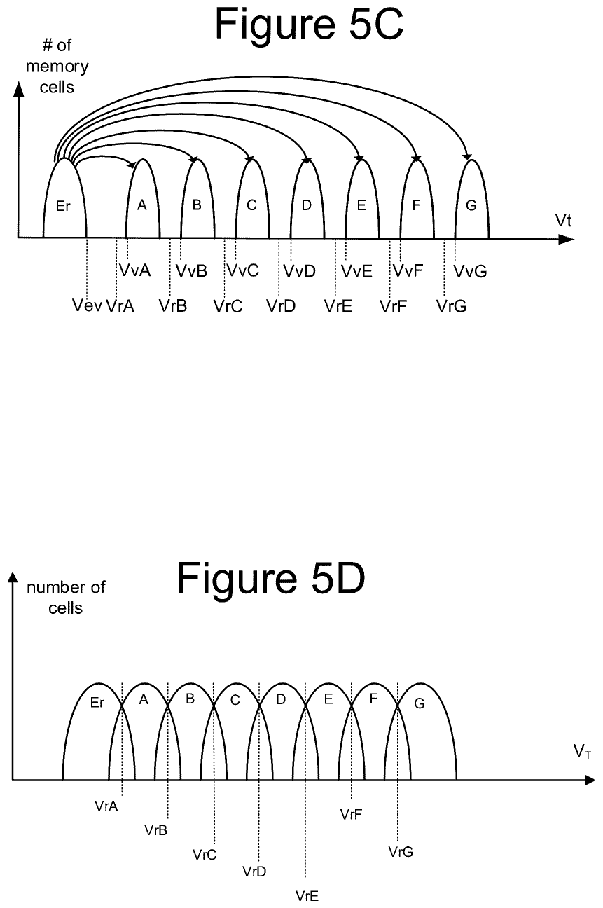

The memory systems discussed above can be erased, programmed and read. At the end of a successful programming process, the threshold voltages of the memory cells should be within one or more distributions of threshold voltages for programmed memory cells or within a distribution of threshold voltages for erased memory cells, as appropriate. FIG. 5A is a graph of threshold voltage versus number of memory cells, and illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. FIG. 5A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 5A depicts read reference voltage Vr. By testing (e.g., performing one or more sense operations) whether the threshold voltage of a given memory cell is above or below Vr, the system can determine a memory cells is erased (state E) or programmed (state P). FIG. 5A also depicts verify reference voltage Vv. In some embodiments, when programming memory cells to data state P, the system will test whether those memory cells have a threshold voltage greater than or equal to Vv.

FIGS. 5B-D illustrate example threshold voltage distributions for the memory array when each memory cell stores multiple bit per memory cell data. Memory cells that store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 5B, each memory cell stores two bits of data. Other embodiments may use other data capacities per memory cell (e.g., such as three, four, or five bits of data per memory cell).

FIG. 5B shows a first threshold voltage distribution E for erased memory cells. Three threshold voltage distributions A, B and C for programmed memory cells are also depicted. In one embodiment, the threshold voltages in the distribution E are negative and the threshold voltages in distributions A, B and C are positive. Each distinct threshold voltage distribution of FIG. 5B corresponds to predetermined values for the set of data bits. In one embodiment, each bit of data of the two bits of data stored in a memory cell are in different logical pages, referred to as a lower page (LP) and an upper page (UP). In other embodiments, all bits of data stored in a memory cell are in a common logical page. The specific relationship between the data programmed into the memory cell and the threshold voltage levels of the cell depends upon the data encoding scheme adopted for the cells. Table 1 provides an example encoding scheme.

TABLE 1

| | E | A | B | C |
|---|---|---|---|---|
| LP | 1 | 0 | 0 | 1 |
| UP | 1 | 1 | 0 | 0 |

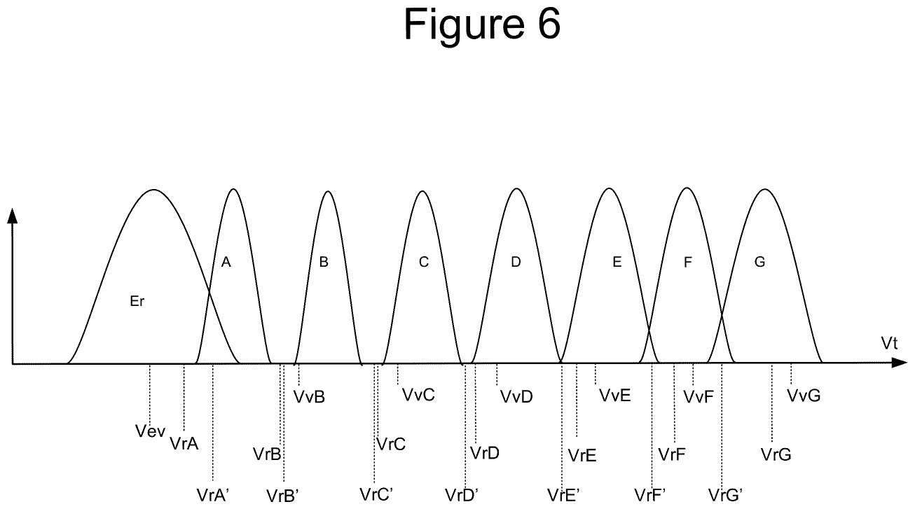

In one embodiment, known as full sequence programming, memory cells can be programmed from the erased data state E directly to any of the programmed data states A, B or C using the process of FIG. 6 (discussed below). For example, a population of memory cells to be programmed may first be erased so that all memory cells in the population are in erased data state E. Then, a programming process is used to program memory cells directly into data states A, B, and/or C. For example, while some memory cells are being programmed from data state E to data state A, other memory cells are being programmed from data state E to data state B and/or from data state E to data state C. The arrows of FIG. 5B represent the full sequence programming. In some embodiments, data states A-C can overlap, with memory controller 120 (or control die 211) relying on error correction to identify the correct data being stored.

FIG. 5C depicts example threshold voltage distributions for memory cells where each memory cell stores three bits of data per memory cells (which is another example of MLC data). FIG. 5C shows eight threshold voltage distributions, corresponding to eight data states. The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected. Table 2 provides an example of an encoding scheme for embodiments in which each bit of data of the three bits of data stored in a memory cell are in different logical pages, referred to as a lower page (LP), middle page (MP) and an upper page (UP).

TABLE 2

| | Er | A | B | C | D | E | F | G |
|---|---|---|---|---|---|---|---|---|
| UP | 1 | 1 | 1 | 0 | 0 | 0 | 0 | 1 |
| MP | 1 | 1 | 0 | 0 | 1 | 1 | 0 | 0 |
| LP | 1 | 0 | 0 | 0 | 0 | 1 | 1 | 1 |

FIG. 5C shows seven read reference voltages VrA, VrB, VrC, VrD, VrE, VrF, and VrG for reading data from memory cells. By testing (e.g., performing sense operations) whether the threshold voltage of a given memory cell is above or below the seven read reference voltages, the system can determine what data state (i.e., A, B, C, D, . . . ) a memory cell is in.

FIG. 5C also shows seven verify reference voltages, VvA, VvB, VvC, VvD, VvE, VvF, and VvG. In some embodiments, when programming memory cells to data state A, the system will test whether those memory cells have a threshold voltage greater than or equal to VvA. When programming memory cells to data state B, the system will test whether the memory cells have threshold voltages greater than or equal to VvB. When programming memory cells to data state C, the system will determine whether memory cells have their threshold voltage greater than or equal to VvC. When programming memory cells to data state D, the system will test whether those memory cells have a threshold voltage greater than or equal to VvD. When programming memory cells to data state E, the system will test whether those memory cells have a threshold voltage greater than or equal to VvE. When programming memory cells to data state F, the system will test whether those memory cells have a threshold voltage greater than or equal to VvF. When programming memory cells to data state G, the system will test whether those memory cells have a threshold voltage greater than or equal to VvG. FIG. 5C also shows Vev, which is an erase verify reference voltage to test whether a memory cell has been properly erased.

In an embodiment that utilizes full sequence programming, memory cells can be programmed from the erased data state Er directly to any of the programmed data states A-G using the process of FIG. 6 (discussed below). For example, a population of memory cells to be programmed may first be erased so that all memory cells in the population are in erased data state Er. Then, a programming process is used to program memory cells directly into data states A, B, C, D, E, F, and/or G. For example, while some memory cells are being programmed from data state Er to data state A, other memory cells are being programmed from data state Er to data state B and/or from data state Er to data state C, and so on. The arrows of FIG. 5C represent the full sequence programming. In some embodiments, data states A-G can overlap, with control die 211 and/or memory controller 120 relying on error correction to identify the correct data being stored. Note that in some embodiments, rather than using full sequence programming, the system can use multi-pass programming processes known in the art.

In general, during verify operations and read operations, the selected word line is connected to a voltage (one example of a reference signal), a level of which is specified for each read operation (e.g., see read compare voltages/levels VrA, VrB, VrC, VrD, VrE, VrF, and VrG, of FIG. 5C) or verify operation (e.g. see verify target voltages/levels VvA, VvB, VvC, VvD, VvE, VvF, and VvG of FIG. 5C) in order to determine whether a threshold voltage of the concerned memory cell has reached such level. After applying the word line voltage, the conduction current of the memory cell is measured to determine whether the memory cell turned on (conducted current) in response to the voltage applied to the word line. If the conduction current is measured to be greater than a certain value, then it is assumed that the memory cell turned on and the voltage applied to the word line is greater than the threshold voltage of the memory cell. If the conduction current is not measured to be greater than the certain value, then it is assumed that the memory cell did not turn on and the voltage applied to the word line is not greater than the threshold voltage of the memory cell. During a read or verify process, the unselected memory cells are provided with one or more read pass voltages (also referred to as bypass voltages) at their control gates so that these memory cells will operate as pass gates (e.g., conducting current regardless of whether they are programmed or erased).

There are many ways to measure the conduction current of a memory cell during a read or verify operation. In one example, the conduction current of a memory cell is measured by the rate it discharges or charges a dedicated capacitor in the sense amplifier. In another example, the conduction current of the selected memory cell allows (or fails to allow) the NAND string that includes the memory cell to discharge a corresponding bit line. The voltage on the bit line is measured after a period of time to see whether it has been discharged or not. Note that the technology described herein can be used with different methods known in the art for verifying/reading. Other read and verify techniques known in the art can also be used.

FIG. 5C shows no overlap between threshold voltage distributions. FIG. 5D depicts an embodiment where each memory cell stores three bits of data per memory cells and the threshold voltage distributions overlap with one or more neighboring threshold voltage distributions. For example, the threshold voltage distribution for data state B overlaps with the threshold voltage distributions for data states A and C. The overlap may occur due to factors such as memory cells losing charge (and hence dropping in threshold voltage). Program disturb can unintentionally increase the threshold voltage of a memory cell. Likewise, read disturb can unintentionally increase the threshold voltage of a memory cell. Over time, the locations of the threshold voltage distributions may change. Such changes can increase the bit error rate, thereby increasing decoding time or even making decoding impossible. Changing the read reference voltages can help to mitigate such effects. Using ECC during the read process can fix errors and ambiguities. In some embodiments, the threshold voltage distributions overlap with one or more neighboring threshold voltage distributions on purpose in order to reduce the size of the window of allowable threshold voltages, which can result in faster programming, lower voltages used and/or lower power used when operating the memory.

Looking back at Table 2, in some embodiments each bit of data of the three bits of data per memory cell are stored in a memory cell are in different logical pages, referred to as a lower page (LP), middle page (MP) and an upper page (UP). For example, the lower page data of a group of memory cells connected to a common word line can be read by sensing at VrA (e.g., applying VrA to the common word line) and sensing at VrE (e.g., applying VrE to the common word line). The middle page data of a group of memory cells connected to a common word line can be read by sensing at VrB (e.g., applying VrB to the common word line), sensing at VrD (e.g., applying VrD to the common word line), and sensing at VrF (e.g., applying VrF to the common word line). The upper page data of a group of memory cells connected to a common word line can be read by sensing at VrC (e.g., applying VrC to the common word line) and sensing at VrG (e.g., applying VrG to the common word line). In one embodiment, the lower bounds of the threshold voltage distributions for states A-G in FIG. 5D will align with VvA, VvB, VvC, VvD, VvE, VvF, and VvG while in other embodiments they will be different (e.g., small difference).

Using the default read reference voltages may, in some cases, result in a read failure due to the inability of the ECC engine 158 to decode the data. FIG. 6 depicts Vt distributions similar to those in FIGS. 5C and 5D, but with the Vt distributions in non-ideal locations. The lower tails of the upper states (e.g., E, F, G) are significantly lower than ideal, as evidenced by the lower tail locations relative to both the verify voltages (e.g., VvE, VvF, VvG) and default read voltages (e.g., VrE, VrF, VrG). Other Vt distributions may also see their lower tail at a lower than ideal location. Some Vt distributions could have the upper tail above an ideal location. For example, the Er-state upper tail is above the erase verify Vev and even above the default A-read level VrA. It is possible that other Vt distributions could also have an upshift in the upper tail.

The Vt distributions could be in the non-ideal locations due to non-physical defect inherent reliability issues such as read disturb or data retention. However, the Vt distributions could also be in non-ideal locations due to a physical defect such as a word line to memory hole short. As one example, a word line to memory hole short may result in word line leakage during program verify, which may reduce the magnitude of the verify voltage on the word line. The lowering of the magnitude of the verify voltage results in a lowering of the Vt of most states (with higher states being impacted to a greater extent). However, the erase state can be disturbed upwards due to the program operation needing more program loops to complete.

Attempting to read using the default read voltages may result in a very high bit error rate (BER), and may even result in a read failure (i.e., inability of the ECC engine 158 to decode the ECC codewords). Therefore, the memory system 100 may change or update the read reference voltages and then retry the read. A number of different techniques may be used to update the read reference voltages. One technique, referred to as a dynamic read table (DRT) read is to access a table of pre-defined shifted read reference voltages. A DRT read involves accessing a table that contains a number of sets of pre-determined read reference voltages. The memory system will select one of the sets of pre-determined read reference voltages and retry the read of the group of memory cells. Other techniques may be used to re-calibrate the read reference voltages based on information collected from reading the memory cells. One technique to re-calibrate the read reference voltages is a “Valley Search Scan.” A Valley Search Scan will read the memory cells to look for a valley between two adjacent Vt distributions. The valley point may be used as the new read reference level (a read reference voltage is one example of a read reference level). Further details of using a Valley Search Scan to determine a target read level are described in U.S. Pat. No. 11,482,296, “ECC in Integrated Memory Assembly,” which is hereby incorporated by reference in its entirety. Another technique to re-calibrate the read reference voltages is referred to as a Bit Error Estimation (BES) read.” A BES read may include sensing memory cells using different sets of read levels and then determining an error that is proportional to the BER, such as syndrome weight (SW), for each set of read reference voltages. Then, the read reference voltage providing the lowest metric (e.g., lowest SW) may be selected as the optimal read reference voltage which is expected to minimize the BER. Further details of using a BES to determine a target read level are described in U.S. Pat. No. 10,991,444, “Tiered Read Reference Calibration,” which is hereby incorporated by reference. Another read technique for which read reference voltages may be re-calibrated is referred to as a “Time Tag Read.” Groups of blocks or WLs that were programmed roughly at the same time and temperature may be associated with a certain time & temperature tag (TT) for which an appropriate set of read reference voltages may be maintained. The read reference voltages of the group associated with a given time & temperature tag may be adjusted from time to time by running a calibration algorithm, such as a valley scan or BES, on representative page(s) from the group.

An example set of updated read reference voltages are depicted (VrA′, VrB′, VrC′, VrD′, VrE′, VrF′, VrG′). In some cases using the updated read reference voltages will still result in a read failure. However, the memory system may use a number of different techniques to derive updated read reference voltages and continue to perform retries until the read is successful. In one embodiment, the memory system will perform physical defect detection following a successful read retry to determine whether there is a physical defect in the block that contains the memory cells or whether the read failure was instead due to a non-physical defect inherent cell reliability issues (e.g., data retention, read disturb). If the memory system determines that there is a physical defect in the block, then the block may be retired. In the event that new read reference voltages cannot be found to successfully read the memory cells, a technique such as an XOR recovery may be used to recover the data that was programmed into the memory cells. However, note that by proactively retiring blocks that are found to have a physical defect, the memory system greatly reduces the chance of needing to resort to XOR recovery or the like. Moreover, pro-actively retiring blocks that are found to have a physical defect alleviates the need for time consuming read retries within the block having the physical defect.

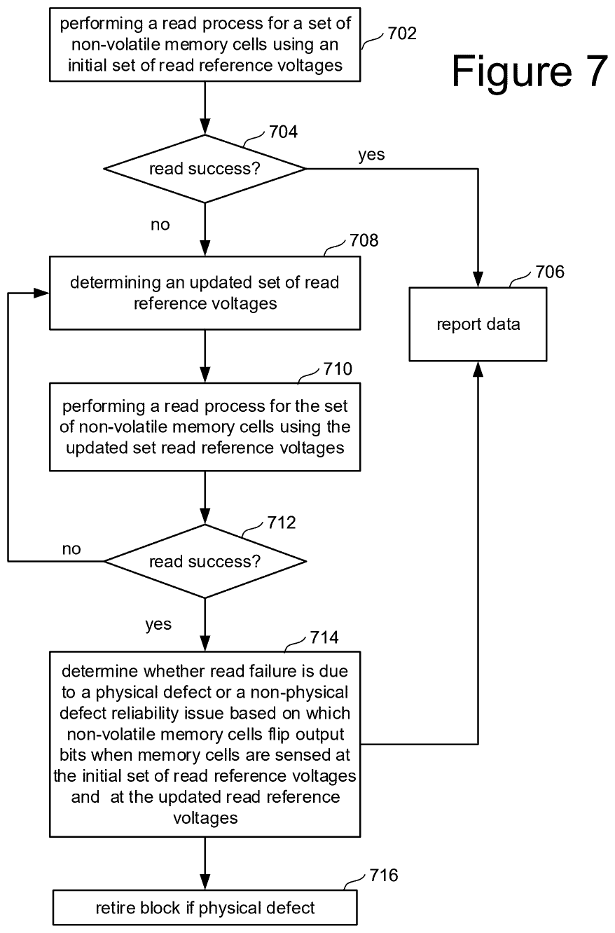

FIG. 7 is a flow chart describing one embodiment of a process for reading non-volatile memory. The process of FIG. 7 can be performed entirely by a control circuit on memory die 200 (see FIG. 2A) or entirely by a control circuit on integrated memory assembly 207 (see FIG. 2B), rather than by memory controller 120. In one example, the process of FIG. 7 is performed by or at the direction of state machine 262, using other components of System Control Logic 260, Column Control Circuitry 210 and Row Control Circuitry 220. In another embodiment, the process of FIG. 7 is performed by memory controller 120 in combination with System Control Logic 260, Column Control Circuitry 210 and Row Control Circuitry 220. In some embodiments, the process of FIG. 7 is performed on any of the non-volatile memories discussed above.

In step 702, the control circuit performs a read process for a set of non-volatile memory cells using an initial set of read reference voltages. For example, all data can be read from a group of memory cells connected to a common word line using all read reference voltages (e.g., VrA-VrG for 3 bits per memory cell), or one page of data can be read using a subset of read reference voltages. If the read process of step 702 was successful (e.g., the data was properly sensed and decoded) (step 704), then the data read is reported back to the client (e.g., host or other entity). If the read process of step 702 was not successful (e.g., the data could not be decoded) (step 704), then the control circuit determines an updated set of read reference voltages using any of the techniques described above or known in the art (step 708). In step 710, the control circuit performs another read process for the same set of non-memory cells using the updated set read reference voltages from step 708. For example, looking at FIG. 6, the read process of step 702 may use one or more of the initial or default read reference voltages VrA-VrG and the read process of step 710 (also known as read retry) may use one or more of the updated read reference voltages VrA′-VrG′. If the read process of step 710 was successful, then in step 714 the control circuit determines whether the read failure of step 702 was due to a physical defect or a non-physical defect reliability issue based on which non-volatile memory cells flip output bits when memory cells are sensed at the initial set of read reference voltages and at the updated set of read reference voltages. More details of step 714 are provided below. After step 714, the data read during step 710 is reported in step 706. Additionally, if in step 714 it was determined that the read failure of step 702 was due to a physical defect, then in step 716 the block of non-volatile memory cells being read is retired from further use by the memory system so that future data is not lost.

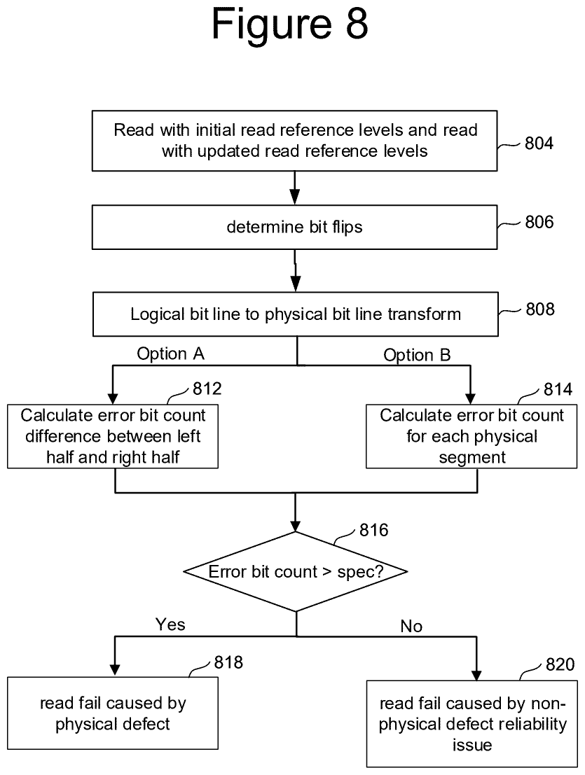

FIG. 8 is a flow chart describing one embodiment of a process for determining whether a read failure was due to a physical defect or a non-physical defect reliability issue based on which non-volatile memory cells flip output bits when memory cells are sensed at the initial set of read reference voltages and at the updated set of read reference voltages. The process of FIG. 8 is one example implementation of step 714 of FIG. 7. The process of FIG. 8 can be performed entirely by a control circuit on memory die 200 (see FIG. 2A) or entirely by a control circuit on integrated memory assembly 207 (see FIG. 2B), rather than by memory controller 120. In one example, the process of FIG. 8 is performed by or at the direction of state machine 262, using other components of System Control Logic 260, Column Control Circuitry 210 and Row Control Circuitry 220. In another embodiment, the process of FIG. 8 is performed by memory controller 120 in combination with System Control Logic 260, Column Control Circuitry 210 and Row Control Circuitry 220. In some embodiments, the process of FIG. 8 is performed on any of the non-volatile memories discussed above.

In step 804, the control circuit performs a first read process using the initial read reference levels. In some embodiments, this is a repeat of step 702. Also in step 804, the control circuit performs a second read process using the updated read reference levels. In some embodiments, this is a repeat of step 710. Step 804 is said to be performing a duo read. In some embodiments, the read reference levels are the read reference voltages discussed above, while in other embodiments different read reference levels can be used. In step 806, the control circuit determines which non-volatile memory cells flipped output bits between the first read process using the initial read reference levels and the second read process using the updated read reference levels.

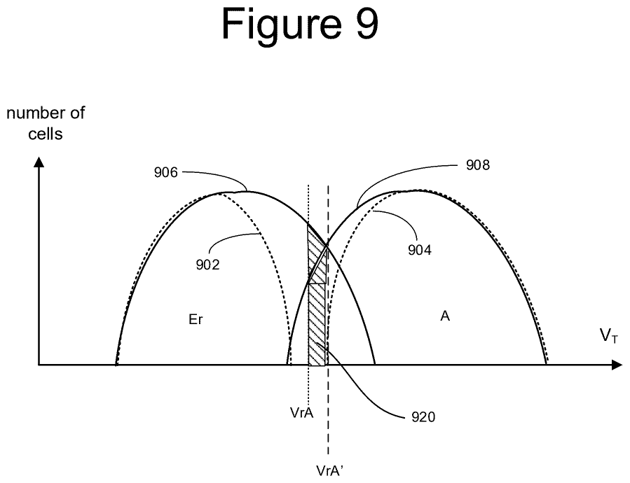

FIG. 9 depicts threshold voltage distributions for memory cells and can be used to illustrate non-volatile memory cells flipping output bits between the first read process using the initial read reference levels and the second read process using the updated read reference levels. More specifically, FIG. 9 depicts threshold voltage distribution 902 (state Er) and threshold voltage distribution 904 (state A) for memory cells right after being programmed with no (or little) errors or defects. Threshold voltage distributions 906 (state Er) and 908 (state A) are for the same memory cells right much later in time after either a physical defect or a non-physical defect reliability issue caused some or all of the memory cells to experience a change in threshold voltage. If a read process is performed using VrA (the first read process of step 804 using initial read reference levels) then there will be many errors. If a read process is performed using VrA′ (the second read process of step 804 using updated read reference levels) then there will be much less errors. The reason there will be less errors when reading with VrA′ is because some of the memory cells that did not turn on (conduct current) in response to VrA will now turn on (conduct current) in response to VrA′. These are the memory cells that flip output bits. The shaded region 920 of FIG. 9 represents memory cells that were sensed to be in state A when using VrA and were sensed to be in state Er when sensed using VrA′. Thus, the memory cells represented by shaded region 920 are the non-volatile memory cells flipped output bits between the first read process using the initial read reference levels and the second read process using the updated read reference levels.

Looking back at FIG. 8, after determining which memory cells flipped output bits in step 806, the control circuit performs a logical bit line to physical bit line transform. In some embodiments, the memory system programs the bit lines as logical bit lines where the numbers of the logical bit lines do not correspond to actual physical location. Physical bit line numbers correspond to actual physical location. In some embodiments, the memory system maintains a mapping of logical bit line numbers to physical bit line numbers (e.g., in volatile memory 140 or storage 266). Clusters of closely located flipped bits may not be evident from logical bit line numbers but may be evident from physical bit line numbers. Step 806 is a determination of the bit flips between the two read operations in terms of logical bit lines, and step 808 translates the identification of logical bit lines to an identification of physical bit lines. The memory controller 120 may have a table, mapping, or the like to transform the logical bit lines to physical bit lines. Thus, after step 808 the memory controller 120 knows the physical location of each memory cell that had a bit flip.

The next steps depend on whether Option A or Option B is to be performed. Option A corresponds to an architecture in which two word line drivers are used to drive a word line. For example, one word line driver may be connected to the left side of the word line and a second word line driver is connected to a second side of the same word line. Step 812 is performed for Option A. Step 812 includes calculating an error bit count (or bit flips) difference between the left half of the block and the right half of the block. The control circuit determines a first total for the bit flips for memory cells connected to the left segment of the word line and a second total for the bit flips for memory cells in the right segment of the word line. Then, the control circuit determines the difference in bit flips between the two segments, which is referred to as the “error bit count.” Next, in step 816, the control circuit determines whether the error bit count is greater than a specification. The specification will factor in the technique used to determine the error bit count. As an example, specification could be whether the error bit count (e.g., difference between right and left sides of the block) is greater than 100. However, the specification could be higher or lower than 100. If the error bit count is greater than the specification then the result is that there is a physical defect and read process (e.g., the read process of step 702) failed because of (or was caused by) the physical defect (step 818). If the error bit count is not greater than the specification then the result is that no physical defect was detected and the read process failed due to a non-physical defect reliability issue (step 820).

Returning again to the steps that follow step 808, step 814 is performed for Option B. Option B may correspond to an architecture with a single word line driver connected to a word line. Step 814 includes calculating an error bit count (or bit flips) difference for each physical segment of the block. As an example, if there are 16 KB bit lines, then the block could be divided into 16 physical segments of 1 KB. The control circuit determines a total number of bit flips for memory cells in each physical segment. In one embodiment, the control circuit is looking for any physical segment having an unusually high number of bit flips. Therefore, the physical segment with the highest number of bit flips is used for the “error bit count” for Option B. Next, in step 816, the control circuit determines whether the error bit count is greater than a specification. The specification will factor in the technique used to determine the error bit count. As an example, specification could be whether the error bit count for any physical segment is greater than 50. However, the specification could be higher or lower than 50 for a physical segment. If the error bit count is greater than the specification then the result is that there is a physical defect and read process (e.g., the read process of step 702) failed because of (or was caused by) the physical defect (step 818). If the error bit count is not greater than the specification then the result is that no physical defect was detected and the read process failed due to a non-physical defect reliability issue (step 820).

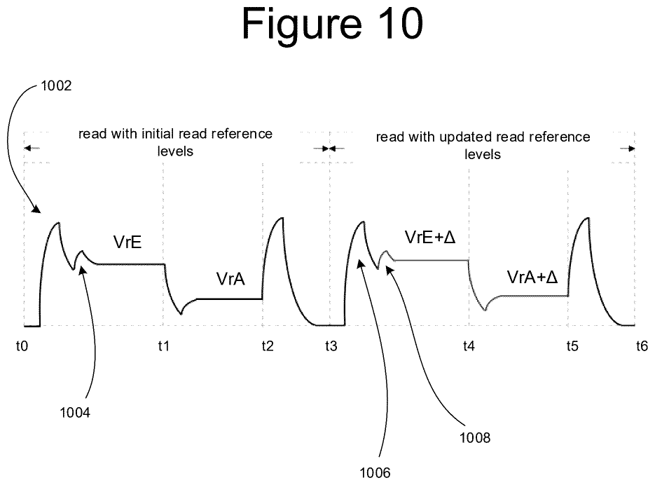

FIG. 10 is a signal diagram depicting the word line voltage (e.g., applied to control gates) applied to memory cells during step 804 when reading a page of data. For example, FIG. 10 depicts reading the lower page of data using VrA and VrE. Between times t0 and t1 the memory system is sensing memory cells in response to applying VrE to the word line connected to the memory cells being sensed (which applies VrE to the control gates of the memory cells being sensed). Between times t1 and t2 the memory system is sensing memory cells in response to applying VrA to the word line connected to the memory cells being sensed (which applies VrA to the control gates of the memory cells being sensed). Time t0-t2 corresponds to the first read process using the initial read reference levels of step 804.

Between times t3 and t4 the memory system is sensing memory cells in response to applying VrE+A to the word line connected to the memory cells being sensed (which applies VrE+A to the control gates of the memory cells being sensed). VrE+A is the updated read reference voltage that was updated from VrE. Between times t4 and t5 the memory system is sensing memory cells in response to applying VrA+A to the word line connected to the memory cells being sensed (which applies VrA+A to the control gates of the memory cells being sensed). VrA+A is the updated read reference voltage that was updated from VrA. Time t3-t5 corresponds to the second read process using the updated read reference levels of step 804.

The word line voltage signal depicted in FIG. 10 also includes voltage spikes 1002 and 1006 to prevent read disturb prior to the first read process and the second read process. After voltage spikes 1002 and 1006, the voltage on the word line need times 1004 and 1008 to settle to the intended read reference voltage. Additionally, between t2 and t3, as well as between t5 and t6, are read recovery voltage spikes to clear out the channel after the read.

FIG. 10 illustrates that the duo read process of step 804 (first read process using the initial read reference levels and second read process using the updated read reference levels) requires a significant amount of time to complete, thereby slowing down the processes of FIGS. 7 and 8 and having a performance impact on the memory system.

In order to speed up the duo read process of step 804 (first read process using the initial read reference levels and second read process using the updated read reference levels) and reduce the performance impact on the memory system, a new and faster duo read process is proposed.

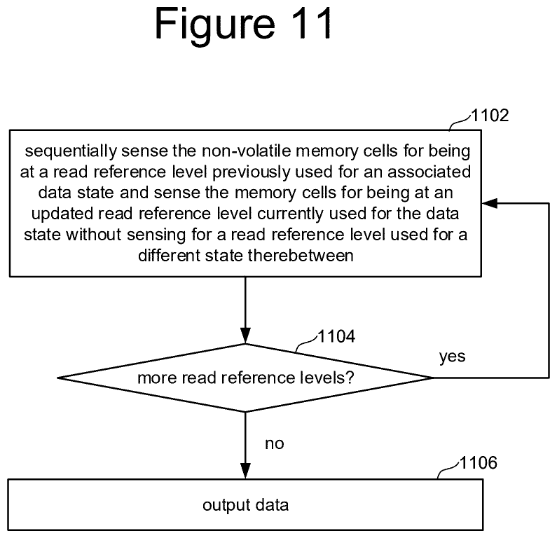

FIG. 11 is a flow chart describing one embodiment of a new and faster duo read process. The process of FIG. 11 is one example implementation of step 804 of FIG. 8. The process of FIG. 11 can be performed entirely by a control circuit on memory die 200 (see FIG. 2A) or entirely by a control circuit on integrated memory assembly 207 (see FIG. 2B), rather than by memory controller 120. In one example, the process of FIG. 11 is performed by or at the direction of state machine 262, using other components of System Control Logic 260, Column Control Circuitry 210 and Row Control Circuitry 220. In another embodiment, the process of FIG. 11 is performed by memory controller 120 in combination with System Control Logic 260, Column Control Circuitry 210 and Row Control Circuitry 220. In some embodiments, the process of FIG. 11 is performed on any of the non-volatile memories discussed above.

In step 1102, the control circuit sequentially senses the non-volatile memory cells for being at a read reference level previously used for an associated data state and senses the memory cells for being at an updated read reference level currently used for the data state without sensing for a read reference level used for a different state therebetween. For example, the control circuit sequentially senses the non-volatile memory cells in response to applying VrE to the word line (and, thereby, the control gates) sequentially with sensing the non-volatile memory cells in response to applying VrE+Δ to the word line (and, thereby, the control gates) without sensing using VrA or VrA+Δ between sensing at VrE and VrE+Δ. In one embodiment, step 1102 is performed for one data state and its associated read reference voltage. In step 1104, it is determined whether more read reference levels need to be sensed for (e.g., whether there are more data states and associated read reference voltages that need to be tested). For example, if step 702 was reading a lower page of data and step 1102 just sensed at VrE and VrE+Δ, then this performance of step 1104 will conclude that there are more read reference levels to test (ie need to test/sense at VrA or VrA+Δ) and the process will loop back to step 1102 to sense at the next set of read reference levels. If there are no more read reference levels to test (step 1104), the data sensed is output in step 1106.

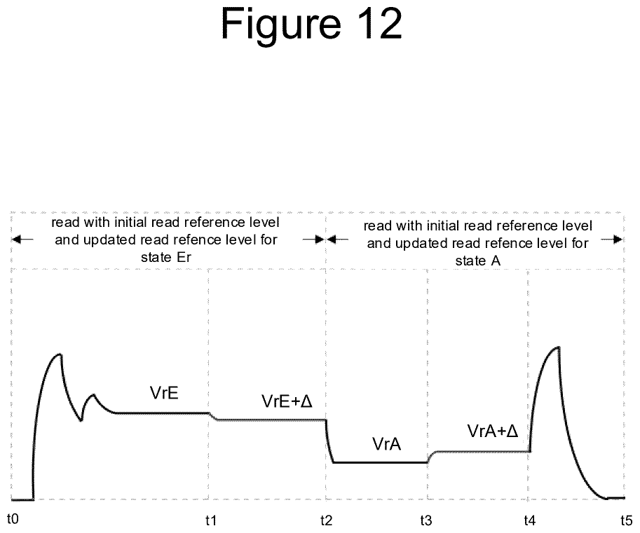

FIG. 12 is a signal diagram depicting the word line voltage (e.g., applied to control gates) applied to memory cells during step 804 when reading a lower page of data using the process of FIG. 11. That is, FIG. 12 depicts sequentially sensing the non-volatile memory cells for being at a read reference level previously used for an associated data state and sensing the memory cells for being at an updated read reference level currently used for the data state without sensing for a read reference level used for a different state therebetween.

Between times t0 and t1 the memory system is sensing memory cells in response to applying VrE to the word line connected to the memory cells being sensed (which applies VrE to the control gates of the memory cells being sensed). Between times t1 and t2 the memory system is sensing memory cells in response to applying VrE+Δ to the word line connected to the memory cells being sensed (which applies VrE+Δ to the control gates of the memory cells being sensed). Time t0-t2 corresponds to the sensing/reading using the initial read reference level and updated read reference level for state E (e.g., between states D and E). Between sensing for VrE and sensing for VrE+A, at time t1 the word line voltage is lowered from VrE directly to VrE+A.

At time t2, the word line voltage is lowered to VrA. Between times t2 and t3 the memory system is sensing memory cells in response to applying VrA to the word line connected to the memory cells being sensed (which applies VrA to the control gates of the memory cells being sensed). Between times t3 and t4 the memory system is sensing memory cells in response to applying VrA+Δ to the word line connected to the memory cells being sensed (which applies VrA+Δ to the control gates of the memory cells being sensed). Time t2-t4 corresponds to the sensing/reading using the initial read reference level and updated read reference level for state A (e.g., between states Er and A).

FIG. 12 depicts sequentially sensing the non-volatile memory cells for being at a read reference level previously used for an associated data state and sensing the memory cells for being at an updated read reference level currently used for the data state without sensing for a read reference level used for a different state therebetween. That is, between sensing at VrE and VrE+Δ, the same memory cells are not sensed for VrA, VrA+Δ or any other read reference voltages of the initial set of read reference voltages or the updated set of read reference voltages.

Note that the A can be negative or positive. That is, an updated read reference voltage can be higher or lower than its corresponding initial read reference voltage. In the example of FIG. 12, VrE>VrE+Δ and VrA<VrA+Δ; however, other permutations can be used.

FIG. 12 shows the duo reading for the lower page. The same techniques for duo reading can be applied to other pages, as well as a read process that senses at all read reference levels.

FIG. 12 depicts sensing at the initial and updated levels for VrA and VrE. However, in some embodiments, the memory system will sense at the initial and updated levels at a subset of read reference levels (e.g., for VrA only and not for VrE, or for VrE and not for VrA).

As described above, the embodiment of FIG. 12 comprises the control circuit sensing the non-volatile memory cells for being at the read reference level previously used for the associated first data state by applying a first read reference voltage to the control gate of the non-volatile memory cells and sensing the memory cells for being at the updated read reference level currently used for the first data state by applying a second read reference voltage to the control gate of the non-volatile memory cells.

FIG. 2C shows that the memory system has a set of latches for each sense amplifier performing sensing. One example of the operation for the latches to implement the embodiment of FIG. 12 is as follows:

$$After sensing at VrE : SEN \to SDL ( the result of sensing is stored in SDL ) \qquad ( 1 )$$

$$After sensing at VrE + Δ : ADL = SDL ⊕ SEN \qquad ( 2 )$$

$$After sensing at VrA : SEN \to SDL \qquad ( 3 )$$

$$After sensing at VrA + Δ : BDL = SDL ⊕ SEN \qquad ( 4 )$$

$$Then XDL = \sim ( ADL \vert BDL ) \qquad ( 5 )$$

The embodiment of FIG. 12 uses one less voltage spike prior to reading and one less voltage spike subsequent to reading as compared to the embodiment of FIG. 10, as well as needs less time for the word line voltage to settle. Therefore, less time is used for the duo reading and system performance is increased.

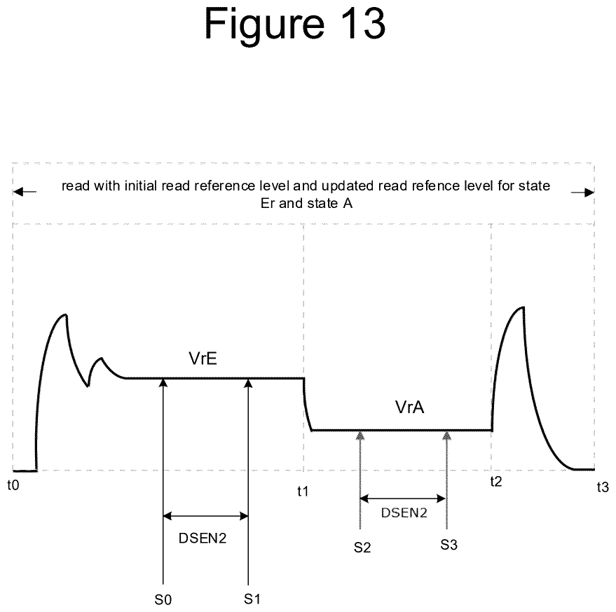

FIG. 13 is a signal diagram depicting the word line voltage (e.g., applied to control gates) applied to memory cells during step 804 when reading a lower page of data using the process of FIG. 11. That is, FIG. 13 depicts sequentially sensing the non-volatile memory cells for being at a read reference level previously used for an associated data state and sensing the memory cells for being at an updated read reference level currently used for the data state without sensing for a read reference level used for a different state therebetween. The embodiment of FIG. 13 comprises the control circuit sensing the non-volatile memory cells for being at the read reference level previously used for the associated first data state by applying a first read reference voltage to the control gate of the non-volatile memory cells and sensing the memory cells for being at the updated read reference level currently used for the associated first data state by also applying the first read reference voltage to the control gate of the non-volatile memory cells, but using a different sense time.

Between times t0 and t1, after the initial voltage spike and settling time, the control circuit applies VrE to the word line connected to the memory cells being sensed so that those memory cells can be sensed for VrE and VrE+Δ. The system can sense for both VrE and VrE+Δ in response to only VrE by sensing at different sense times. In one example, the memory cells will be sensed at a first sense time S0 for VrE and at a second sense time S1 for VrE+Δ. DSEN2 represents the time difference between S0 and S1.

Between times t1 and t2 the control circuit applies VrA to the word line connected to the memory cells being sensed so that those memory cells can be sensed for VrA and VrA+Δ. The system can sense for both VrA and VrA+Δ in response to only VrA by sensing at different sense times. In one example, the memory cells will be sensed at a first sense time S2 for VrA and at a second sense time S3 for VrA+Δ. DSEN2 represents the time difference between S2 and S3.

The embodiment of FIG. 13 uses one less voltage spike prior to reading and one less voltage spike subsequent to reading as compared to the embodiment of FIG. 10, as well as needs less time for the word line voltage to settle. Therefore, less time is used for the duo reading and system performance is increased.

FIG. 13 shows the duo reading for the lower page. The same techniques for duo reading can be applied to other pages, as well as a read that senses at all read reference levels.

FIG. 13 depicts sense at the initial and updated levels for VrA and VrE. However, in some embodiments, the memory system will sense at the initial and updated levels at a subset of read reference levels (e.g., for VrA only and not for VrE, or at VrE only and not for VrA).

One example of the operation for the latches to implement the embodiment of FIG. 13 is as follows:

$$After sensing at VrE : SEN \to SDL ( @ S 0 ) , ADL = SDL ⊕ SEN ( @ S 1 ) , \qquad ( 1 )$$

$$After sensing at VrA : SEN \to SDL ( @ S 2 ) , BDL = SDL ⊕ SEN ( @ S 3 ) , \qquad ( 2 )$$

$$Then XDL = \sim ( ADL \vert BDL ) \qquad ( 3 )$$

The particular example depicted in FIG. 13 assumes that VrE>VrE+Δ and VrA>VrA+Δ. However, the A need not always be negative. In some cases, the A could be positive. Thus, the graph of FIG. 13 can be adapted such that the voltage applied to the word line is the higher voltage of the initial voltage and updated voltage, and the system senses for the lower read reference voltage first followed by sensing for the higher read reference voltage. That is, if VrE<VrE+Δ, then apply VrE+Δ to the word line and sense for VrE first. If VrE>VrE+Δ, then apply VrE to the word line and sense for VrE+Δ first. The system applies to the word line the larger voltage of the initial voltage and updated voltage and sense at the two different times (first for the lower and second for the higher). Thus, two sensing are performed for each read reference voltage pair (initial and updated), without recharging the bit line therebetween.

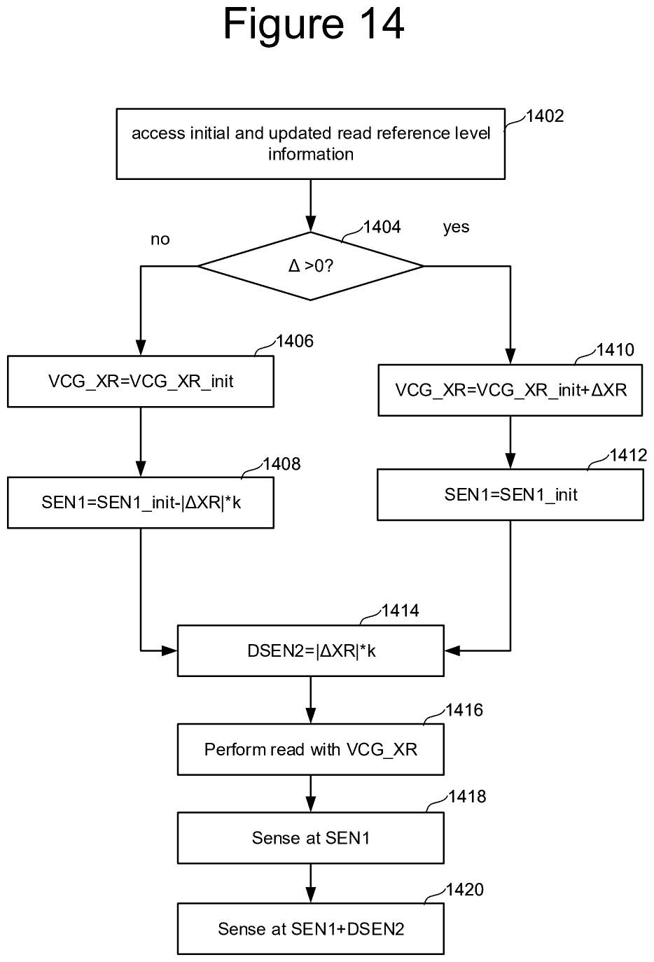

FIG. 14 is a flow chart describing one embodiment of the duo read process depicted in FIG. 13 that includes sequentially sensing the non-volatile memory cells for being at a read reference level previously used for an associated data state and sensing the memory cells for being at an updated read reference level currently used for the data state without sensing for a read reference level used for a different state therebetween. The process of FIG. 14 can be performed entirely by a control circuit on memory die 200 (see FIG. 2A) or entirely by a control circuit on integrated memory assembly 207 (see FIG. 2B), rather than by memory controller 120. In one example, the process of FIG. 14 is performed by or at the direction of state machine 262, using other components of System Control Logic 260, Column Control Circuitry 210 and Row Control Circuitry 220. In another embodiment, the process of FIG. 14 is performed by memory controller 120 in combination with System Control Logic 260, Column Control Circuitry 210 and Row Control Circuitry 220. In some embodiments, the process of FIG. 14 is performed on any of the non-volatile memories discussed above.

The process of FIG. 14 comprises the control circuit sensing the non-volatile memory cells for being at the read reference level previously used for the associated first data state by applying a first read reference voltage to the control gate of the non-volatile memory cells and sensing the memory cells for being at the updated read reference level currently used for the associated first data state by also applying the first read reference voltage to the control gate of the non-volatile memory cells, but using a different sense time.

The process of FIG. 14 uses several parameters. The parameter VCG_XR is the read reference voltage being applied to the word line. Examples of VCG_XR are VrE and VrA of FIG. 13. The parameter SEN1 is the first sense time for sensing at a read reference level. Examples of SEN1 in FIG. 13 are S0 and S2. DSEN2 is the time difference between the first sense time and the second time, as depicted in FIG. 13. The parameter VCG_XR_init is the initial read reference level previously used for an associated data state. The read failure occurred using VCG_XR_init. The parameter ΔXR is the change in the read reference level from the initial read reference level previously used for an associated data state to the updated read reference level. The parameter SEN1_init is the sense time for the initial read reference level previously used for an associated data state. The parameter k is an implementation specific constant.

In step 1403, the control circuit accesses initial and updated read reference level information for state X (e.g., any state). If the updated read reference level is greater than the initial read reference level, then Δ>0. If the updated read reference level is less than the initial read reference level, then Δ<0. In step 1404 it is determined whether Δ>0. If so, the process continues at step 1410 with VCG_XR being set to be VCG_XR=VCG_XR_init+ΔXR and step 1412 with SEN1 being set to be SEN1=SEN1_init. If in step 1404 it is determined that Δ<0, then the process continues at step 1406 with VCG_XR being set to be VCG_XR=VCG_XR_init and step 1408 with SEN1 being set to be SEN1=SEN1_init−|ΔXR|*k. In step 1414 (after either step 1406 or step 1412), DSEN2 is set to DSEN2=|ΔXR|*k. In step 1416, the read operation is set up. The voltage to be applied to the word line is the higher of the initial read reference level previously used for the associated data state and the updated read reference level for the associated data state. In step 1418, the control circuit (e.g., sense amplifiers) senses at time SEN1. In step 1420, the control circuit (e.g., sense amplifiers) senses at time SEN1+DSEN2.

In some embodiments, the duo read process is performed for all read reference levels and for all pages. In other embodiments, the duo read process is performed for a subset read reference voltages and/or for a subset of pages. For example, looking back at FIGS. 12 and 13, the duo read can be performed for VrA but not VrE. In another example, it has been observed that a word line to memory hole short results in a downward shift of threshold voltages for memory cells in state G to state F and for memory cells in state A to state Er. Thus, the duo read can be performed for only the upper page, only the lower page, only the upper page and lower page, only for VrA, only for VrG, or only for VrA and VrG.

When only performing the duo read for a single state, one example of the data latch operation is as follows:

$$After read at VrG : SEN \to SDL \qquad ( 1 )$$

$$After read at VrG with Δ VrG : XDL = SDL ⊕ SEN \qquad ( 2 )$$

Or in two-steps sensing manner:

$$After read at VrG : SEN \to SDL ( @ TSEN 1 ) , XDL = SDL ⊕ SEN ( @ TSEN 2 ) \qquad ( 1 )$$

In order to speed up the duo read process of step 804 (first read process using the initial read reference levels and second read process using the updated read reference levels) and reduce the performance impact on the memory system, a new and faster duo read process has been proposed.

One embodiment includes a non-volatile storage apparatus comprising non-volatile memory cells and a control circuit connected to the non-volatile memory cells. The control circuit is configured to read data from the non-volatile memory cells including sensing the non-volatile memory cells for being at different read reference levels. Each of the different read reference levels is associated with a different data state. For at least one of the different read reference levels the control circuit is configured to sequentially sense the non-volatile memory cells for being at a read reference level previously used for an associated first data state and sense the memory cells for being at an updated read reference level currently used for the first data read.

In one embodiment, the control circuit is further configured to determine whether a read failure is due to a physical defect or a non-physical defect reliability issue based on which non-volatile memory cells flip output bits when memory cells are sensed at the read reference level previously used for the associated first data state and sensed at the updated read reference level currently used for the first data state.

In one embodiment, the control circuit is further configured to read data from the non-volatile memory cells by: performing a first read process for the non-volatile memory cells using an initial set read reference levels, the initial set read reference levels include the read reference level previously used for the associated first data state; determining that the first read process failed; determining an updated set of read reference levels, the updated set of read reference levels include the updated read reference level currently used for the first data state; performing a second read process for the set of non-volatile memory cells using the updated set read reference levels; determining that the second read process succeeded; and performing a third read process that uses the initial set read reference levels and the updated set of read reference levels such that non-volatile memory cells are sensed at the read reference level previously used for the associated first data state sequentially with being sensed at the updated read reference level currently used for the first data state without sensing therebetween at a different read reference level of either the initial set read reference levels or the updated set read reference levels. In some implementations, the control circuit is further configured to: determine memory cells that flip output bits between sensing at the read reference level previously used for the associated first data state and sensing at read reference level previously used for the associated first data state during the third read process; and determine whether the first read process failed due to a physical defect or a non-physical defect reliability issue based on which non-volatile memory cells were determined to have flipped output bits.

In one embodiment, the control circuit is configured to sense the non-volatile memory cells for being at the read reference level previously used for the associated first data state by applying a first read reference voltage to the control gate of the non-volatile memory cells; the control circuit is configured to sense the memory cells for being at the updated read reference level currently used for the first data state by applying a second read reference voltage to the control gate of the non-volatile memory cells; and the first read reference voltage is different than the second read reference voltage. The first read reference voltage can be less than the second read reference voltage. The first read reference voltage can greater than the second read reference voltage.

In one embodiment, the control circuit is configured to, subsequent to the sequentially sensing the non-volatile memory cells for being at the read reference level previously used for the associated first data state and sensing the memory cells for being at the updated read reference level currently used for the first data state without sensing for a read reference level used for a different state therebetween, sequentially sense the non-volatile memory cells for being at the read reference level previously used for an associated second data state and sense the memory cells for being at an updated read reference level currently used for the second data state without sensing for a read reference level used for a different state therebetween. In some implementations, the sensing of the non-volatile memory cells for being at the read reference level previously used for the associated first data state, the sensing the non-volatile memory cells for being at the updated read reference level currently used for the first data state, the sensing the non-volatile memory cells for being at the read reference level previously used for the associated second data state and sensing the memory cells for being at the updated read reference level currently used for the second data state are for reading a first page of data; and the control circuit is configured to not use read reference levels previously used for other pages of data. The control circuit is configured to use read reference levels previously used for other pages of data.

In one embodiment, the control circuit is configured to sense the non-volatile memory cells for being at the read reference level previously used for the associated first data state by applying a first read reference voltage to the control gate of the non-volatile memory cells; and the control circuit is configured to sense the memory cells for being at the updated read reference level currently used for the associated first data state by applying the first read reference voltage to the control gate of the non-volatile memory cells.

In one embodiment, the control circuit is configured to sense the non-volatile memory cells for being at the read reference level previously used for the associated first data state by applying a first read reference voltage to the control gate of the non-volatile memory cells and sensing after a first sense time; and the control circuit is configured to sense the memory cells for being at the updated read reference level currently used for the associated first data state by applying the first read reference voltage to the control gate of the non-volatile memory cells and sensing after a second sense time.

In one embodiment, the control circuit is configured to sense the non-volatile memory cells for being at the read reference level previously used for the associated first data state by sensing in response to the first read reference voltage after a first sense time; the control circuit is configured to sense the memory cells for being at the updated read reference level currently used for the first data state by sensing in response to the first read reference voltage after a second sense time; and the first sense time is different than the second sense time. In some implementations, the first read reference voltage corresponds to the read reference level previously used for the associated first data; the updated read reference level currently used for the first data state is greater than the read reference level previously used for the associated first data; and the first sense time is less than the second sense time.

In one embodiment, the first read reference voltage corresponds to the updated read reference level currently used for the first data state; the updated read reference level currently used for the first data state is less than the read reference level previously used for the associated first data; and the first sense time is greater than the second sense time.

One embodiment includes a method, comprising: performing a first read process for a set of non-volatile memory cells using an initial set read reference voltages; determining that the first read process failed; determining an updated set of read reference voltages; performing a second read process for the set of non-volatile memory cells using the updated set read reference voltages; determining that the second read process succeeded; performing a third read process that uses the initial set read reference voltages and the updated set of read reference voltages such that non-volatile memory cells are sensed at a particular read reference voltage of the first set read reference voltages sequentially with being sensed at a corresponding particular read reference voltage of the updated set of read reference voltages without sensing therebetween at a different read reference voltage of either the initial set read reference voltages or the updated set read reference voltages; determining memory cells that flip output bits between sensing at the particular read reference voltage of the first set read reference voltages and sensing at the corresponding particular read reference of the updated set of read reference voltages during the third read process; and determine whether the first read process failed due to a physical defect or a non-physical defect reliability issue based on the memory cells that flip output bits.

In one embodiment, the non-volatile memory cells are sensed at the particular read reference voltage of the first set read reference voltages sequentially with being sensed at the corresponding particular read reference of the updated set of read reference voltages without sensing therebetween by applying a first read reference voltage to the control gate of the non-volatile memory cells and sensing in response to the first read reference voltage followed by applying a second read reference voltage to the control gate of the non-volatile memory cells and sensing in response to the second read reference voltage, the first read reference voltage is different than the second read reference voltage.

In one embodiment, the non-volatile memory cells are sensed at the particular read reference voltage of the first set read reference voltages sequentially with being sensed at the corresponding particular read reference of the updated set of read reference voltages without sensing therebetween by applying a first read reference voltage associated with a first data state to the control gate of the non-volatile memory cells and sensing in response to the first read reference voltage followed by applying a second read reference voltage associated with the first data state to the control gate of the non-volatile memory cells and sensing in response to the second read reference voltage followed by applying a third read reference voltage associated with a second data state to the control gate of the non-volatile memory cells and sensing in response to the third read reference voltage followed by applying a fourth read reference voltage associated with the second data state to the control gate of the non-volatile memory cells and sensing in response to the fourth read reference voltage.

In one embodiment, the non-volatile memory cells are sensed at the particular read reference voltage of the first set read reference voltages sequentially with being sensed at the corresponding particular read reference of the updated set of read reference voltages without sensing therebetween by: applying a first read reference voltage to the control gate of the non-volatile memory cells; sensing in response to the first read reference voltage at a first sensing time; and sensing in response to the first read reference voltage at a second sensing time.

One embodiment includes a non-volatile storage apparatus, comprising non-volatile memory cells and a control circuit connected to the non-volatile memory cells. The control circuit is configured to read data from the non-volatile memory cells and determine whether a read failure is due to a physical defect or a non-physical defect reliability issue based on which non-volatile memory cells flip output bits when the non-volatile memory cells are sensed at a particular read reference voltage of an initial set read reference voltages used before the read failure sequentially with being sensed at a corresponding particular read reference of an updated set of read reference voltages without sensing therebetween at a different read reference voltage of either the initial set read reference voltages or the updated set read reference voltages.

For purposes of this document, the means for reading data can be implemented by any of the embodiments of a control circuit described above (see e.g., FIGS. 1-2C), including a microprocessor or microcontroller, performing the process of FIGS. 9, 10, 12 and/or 14.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A non-volatile storage apparatus, comprising:
non-volatile memory cells; and
a control circuit connected to the non-volatile memory cells, the control circuit is configured to read data from the non-volatile memory cells including sensing the non-volatile memory cells for being at different read reference levels, each of the different read reference levels is associated with a different data state, for at least one of the different read reference levels the control circuit is configured to sequentially sense the non-volatile memory cells for being at a read reference level previously used for an associated first data state and sense the memory cells for being at an updated read reference level currently used for the first data read.

2. The non-volatile storage apparatus of claim 1, wherein:
the control circuit is further configured to determine whether a read failure is due to a physical defect or a non-physical defect reliability issue based on which non-volatile memory cells flip output bits when memory cells are sensed at the read reference level previously used for the associated first data state and sensed at the updated read reference level currently used for the first data state.

3. The non-volatile storage apparatus of claim 1, wherein the control circuit is further configured to read data from the non-volatile memory cells by:
performing a first read process for the non-volatile memory cells using an initial set read reference levels, the initial set read reference levels include the read reference level previously used for the associated first data state;
determining that the first read process failed;
determining an updated set of read reference levels, the updated set of read reference levels include the updated read reference level currently used for the first data state;
performing a second read process for the set of non-volatile memory cells using the updated set read reference levels;
determining that the second read process succeeded; and
performing a third read process that uses the initial set read reference levels and the updated set of read reference levels such that non-volatile memory cells are sensed at the read reference level previously used for the associated first data state sequentially with being sensed at the updated read reference level currently used for the first data state without sensing therebetween at a different read reference level of either the initial set read reference levels or the updated set read reference levels.

4. The non-volatile storage apparatus of claim 3, wherein the control circuit is further configured to:
determine memory cells that flip output bits between sensing at the read reference level previously used for the associated first data state and sensing at read reference level previously used for the associated first data state during the third read process; and
determine whether the first read process failed due to a physical defect or a non-physical defect reliability issue based on which non-volatile memory cells were determined to have flipped output bits.

5. The non-volatile storage apparatus of claim 1, wherein:
the control circuit is configured to sense the non-volatile memory cells for being at the read reference level previously used for the associated first data state by applying a first read reference voltage to the control gate of the non-volatile memory cells;
the control circuit is configured to sense the memory cells for being at the updated read reference level currently used for the first data state by applying a second read reference voltage to the control gate of the non-volatile memory cells; and
the first read reference voltage is different than the second read reference voltage.

6. The non-volatile storage apparatus of claim 5, wherein:
the first read reference voltage is less than the second read reference voltage.

7. The non-volatile storage apparatus of claim 5, wherein:
the first read reference voltage is greater than the second read reference voltage.

8. The non-volatile storage apparatus of claim 1, wherein:
the control circuit is configured to, subsequent to the sequentially sensing the non-volatile memory cells for being at the read reference level previously used for the associated first data state and sensing the memory cells for being at the updated read reference level currently used for the first data state without sensing for a read reference level used for a different state therebetween, sequentially sense the non-volatile memory cells for being at the read reference level previously used for an associated second data state and sense the memory cells for being at an updated read reference level currently used for the second data state without sensing for a read reference level used for a different state therebetween.

9. The non-volatile storage apparatus of claim 8, wherein:
the sensing of the non-volatile memory cells for being at the read reference level previously used for the associated first data state, the sensing the non-volatile memory cells for being at the updated read reference level currently used for the first data state, the sensing the non-volatile memory cells for being at the read reference level previously used for the associated second data state and sensing the memory cells for being at the updated read reference level currently used for the second data state are for reading a first page of data; and
the control circuit is configured to not use read reference levels previously used for other pages of data.

10. The non-volatile storage apparatus of claim 9, wherein:
the control circuit is configured to use read reference levels previously used for other pages of data.

11. The non-volatile storage apparatus of claim 1, wherein:
the control circuit is configured to sense the non-volatile memory cells for being at the read reference level previously used for the associated first data state by applying a first read reference voltage to the control gate of the non-volatile memory cells; and
the control circuit is configured to sense the memory cells for being at the updated read reference level currently used for the associated first data state by applying the first read reference voltage to the control gate of the non-volatile memory cells.

12. The non-volatile storage apparatus of claim 1, wherein:
the control circuit is configured to sense the non-volatile memory cells for being at the read reference level previously used for the associated first data state by applying a first read reference voltage to the control gate of the non-volatile memory cells and sensing after a first sense time; and
the control circuit is configured to sense the memory cells for being at the updated read reference level currently used for the associated first data state by applying the first read reference voltage to the control gate of the non-volatile memory cells and sensing after a second sense time.

13. The non-volatile storage apparatus of claim 1, wherein:
the control circuit is configured to sense the non-volatile memory cells for being at the read reference level previously used for the associated first data state by sensing in response to the first read reference voltage after a first sense time;
the control circuit is configured to sense the memory cells for being at the updated read reference level currently used for the first data state by sensing in response to the first read reference voltage after a second sense time; and
the first sense time is different than the second sense time.

14. The non-volatile storage apparatus of claim 13, wherein:
the first read reference voltage corresponds to the read reference level previously used for the associated first data;
the updated read reference level currently used for the first data state is greater than the read reference level previously used for the associated first data; and
the first sense time is less than the second sense time.

15. The non-volatile storage apparatus of claim 1, wherein:
the first read reference voltage corresponds to the updated read reference level currently used for the first data state;
the updated read reference level currently used for the first data state is less than the read reference level previously used for the associated first data; and
the first sense time is greater than the second sense time.

16. A method, comprising:
performing a first read process for a set of non-volatile memory cells using an initial set read reference voltages;
determining that the first read process failed;
determining an updated set of read reference voltages;
performing a second read process for the set of non-volatile memory cells using the updated set read reference voltages;
determining that the second read process succeeded;
performing a third read process that uses the initial set read reference voltages and the updated set of read reference voltages such that non-volatile memory cells are sensed at a particular read reference voltage of the first set read reference voltages sequentially with being sensed at a corresponding particular read reference voltage of the updated set of read reference voltages without sensing therebetween at a different read reference voltage of either the initial set read reference voltages or the updated set read reference voltages;
determining memory cells that flip output bits between sensing at the particular read reference voltage of the first set read reference voltages and sensing at the corresponding particular read reference of the updated set of read reference voltages during the third read process; and
determine whether the first read process failed due to a physical defect or a non-physical defect reliability issue based on the memory cells that flip output bits.

17. The method of claim 16, wherein the non-volatile memory cells are sensed at the particular read reference voltage of the first set read reference voltages sequentially with being sensed at the corresponding particular read reference of the updated set of read reference voltages without sensing therebetween by:
applying a first read reference voltage to the control gate of the non-volatile memory cells and sensing in response to the first read reference voltage followed by applying a second read reference voltage to the control gate of the non-volatile memory cells and sensing in response to the second read reference voltage, the first read reference voltage is different than the second read reference voltage.

18. The method of claim 16, wherein the non-volatile memory cells are sensed at the particular read reference voltage of the first set read reference voltages sequentially with being sensed at the corresponding particular read reference of the updated set of read reference voltages without sensing therebetween by:
applying a first read reference voltage associated with a first data state to the control gate of the non-volatile memory cells and sensing in response to the first read reference voltage followed by applying a second read reference voltage associated with the first data state to the control gate of the non-volatile memory cells and sensing in response to the second read reference voltage followed by applying a third read reference voltage associated with a second data state to the control gate of the non-volatile memory cells and sensing in response to the third read reference voltage followed by applying a fourth read reference voltage associated with the second data state to the control gate of the non-volatile memory cells and sensing in response to the fourth read reference voltage.

19. The method of claim 16, wherein the non-volatile memory cells are sensed at the particular read reference voltage of the first set read reference voltages sequentially with being sensed at the corresponding particular read reference of the updated set of read reference voltages without sensing therebetween by:
applying a first read reference voltage to the control gate of the non-volatile memory cells;
sensing in response to the first read reference voltage at a first sensing time; and
sensing in response to the first read reference voltage at a second sensing time.

20. A non-volatile storage apparatus, comprising:
non-volatile memory cells; and
a control circuit connected to the non-volatile memory cells, the control circuit is configured to:
read data from the non-volatile memory cells, and
determine whether a read failure is due to a physical defect or a non-physical defect reliability issue based on which non-volatile memory cells flip output bits when the non-volatile memory cells are sensed at a particular read reference voltage of an initial set read reference voltages used before the read failure sequentially with being sensed at a corresponding particular read reference of an updated set of read reference voltages without sensing therebetween at a different read reference voltage of either the initial set read reference voltages or the updated set read reference voltages.
